(19) United States
(12) Patent Application Publication
(10) Pub. No.: US 2023/0269925 A1
(43) Pub. Date: Aug. 24, 2023

(54) METHOD FOR MANUFACTURING MEMORY DEVICE INCLUDING PILLAR-SHAPED SEMICONDUCTOR ELEMENT

(71) Applicant: Unisantis Electronics Singapore Pte, Ltd., Singapore (SG)

(72) Inventors: Nozomu HARADA, Tokyo (JP); Koji SAKUI, Tokyo (JP)

(21) Appl. No.: 18/304,721

(22) Filed: Apr. 21, 2023

Related U.S. Application Data
(63) Continuation-in-part of application No. 17/478,282, filed on Sep. 17, 2021.
(63) Continuation-in-part of application No. PCT/JP2021/002251, filed on Jan. 22, 2021.
Application No. 17/478,282 is a continuation of application No. PCT/JP2020/048952, filed on Dec. 25, 2020.

(51) Int. Cl. H10B 12/00

(52) U.S. Cl. CPC H10B 12/20; H10B 12/01

(57) ABSTRACT

An N⁺ layer connected to a source line SL at both ends of individual Si pillars standing in a vertical direction; N⁺ layers connected to a bit line BL1; N⁺ layers connected to a bit line BL2; a TiN layer surrounding gate HfO₂ layers surrounding the individual Si pillars, being continuous between the individual Si pillars, and connected to a plate line PL; a TiN layer surrounding gate HfO₂ layers surrounding the four Si pillars, being continuous between the individual Si pillars, and connected to a word line WL1; and a TiN layer connected to a word line WL2 are formed on a substrate. Voltages to be applied to the source line SL, the plate line PL, the word lines WL1 and WL2, and the bit lines BL1 and BL2 are controlled to perform a data hold operation of holding, in any or all of the Si pillars, a positive hole group generated by an impact ionization phenomenon or a gate-induced drain-leakage current, and a data erase operation of discharging the positive hole group from the Si pillars.

### CROSS REFERENCES TO RELATED APPLICATIONS

The present application is a continuation-in-part application of Ser.No.17/478,282 filed Sep. 17, 2021, which is a continuation of PCT/JP2020/048952, filed on Dec. 25, 2020. The present application is also a continuation-in part application of PCT/JP2021/002251, filed Jan. 22, 2021, the entire contents of which are incorporated herein by reference.

### BACKGROUND OF THE INVENTION

### 1. Field of the Invention

The present invention relates to a method for manufacturing a memory device including a pillar-shaped semiconductor element.

### 2. Description of the Related Art

In recent years, higher integration and higher performance of memory elements have been demanded in the development of the large scale integration (LSI) technology.

In a typical planar metal oxide semiconductor (MOS) transistor, a channel extends in a horizontal direction along an upper surface of a semiconductor substrate. In contrast, in a surrounding gate transistor (SGT), a channel extends in a vertical direction with respect to an upper surface of a semiconductor substrate (see, for example, Japanese Unexamined Patent Application Publication No. 2-188966; and Hiroshi Takato, Kazumasa Sunouchi, Naoko Okabe, Akihiro Nitayama, Katsuhiko Hieda, Fumio Horiguchi, and Fujio Masuoka: IEEE Transaction on Electron Devices, Vol. 38, No. 3, pp. 573-578 (1991)). Thus, compared with the planar MOS transistor, the SGT is capable of increasing the density of a semiconductor device. With use of the SGT as a selection transistor, higher integration can be achieved in a dynamic random access memory (DRAM) to which a capacitor is connected (see, for example, H. Chung, H. Kim, H. Kim, K. Kim, S. Kim, K. W. Song, J. Kim, Y. C. Oh, Y. Hwang, H. Hong, G. Jin, and C. Chung: “4F2 DRAM Cell with Vertical Pillar Transistor (VPT)”, 2011 Proceeding of the European Solid-State Device Research Conference, (2011)), a phase change memory (PCM) to which a resistance change element is connected (see, for example, H. S. Philip Wong, S. Raoux, S. Kim, Jiale Liang, J. R. Reifenberg, B. Rajendran, M. Asheghi and K. E. Goodson: “Phase Change Memory”, Proceeding of IEEE, Vol. 98, No. 12, December, pp. 2201-2227 (2010)), a resistive random access memory (RRAM) (see, for example, K. Tsunoda, K. Kinoshita, H. Noshiro, Y. Yamazaki, T. Iizuka, Y. Ito, A. Takahashi, A. Okano, Y. Sato, T. Fukano, M. Aoki, and Y. Sugiyama: “Low Power and High Speed Switching of Ti-doped NiO ReRAM under the Unipolar Voltage Source of less than 3 V”, IEDM (2007)), a magneto-resistive random access memory (MRAM) in which a resistance is changed by changing the orientation of a magnetic spin by using a current (see, for example, W. Kang, L. Zhang, J. Klein, Y. Zhang, D. Ravelosona, and W. Zhao: “Reconfigurable Codesign of STT-MRAM Under Process Variations in Deeply Scaled Technology”, IEEE Transaction on Electron Devices, pp. 1-9 (2015); and M. G. Ertosun, K. Lim, C. Park, J. Oh, P. Kirsch, and K. C. Saraswat: “Novel Capacitorless Single-Transistor Charge-Trap DRAM (1T CT DRAM) Utilizing Electron”, IEEE Electron Device Letter, Vol. 31, No. 5, pp. 405-407 (2010)), and so forth. In addition, there is a capacitorless DRAM memory cell constituted by a single MOS transistor (see, for example, J. Wan, L. Rojer, A. Zaslavsky, and S. Critoloveanu: “A Compact Capacitor-Less High-Speed DRAM Using Field Effect-Controlled Charge Regeneration”, Electron Device Letters, Vol. 35, No. 2, pp. 179-181 (2012)). The present application relates to a dynamic flash memory that does not include a resistance change element or a capacitor and that can be constituted by a MOS transistor alone.

FIGS. 7A to 7D illustrate a write operation of the above-described capacitorless DRAM memory cell constituted by a single MOS transistor, FIGS. 8A and 8B illustrate a problem in the operation, and FIGS. 9A to 9C illustrate a read operation (see J. Wan, L. Rojer, A. Zaslavsky, and S. Critoloveanu: “A Compact Capacitor-Less High-Speed DRAM Using Field Effect-Controlled Charge Regeneration”, Electron Device Letters, Vol. 35, No. 2, pp. 179-181 (2012); T. Ohsawa, K. Fujita, T. Higashi, Y. Iwata, T. Kajiyama, Y. Asao, and K. Sunouchi: “Memory design using a one-transistor gain cell on SOI”, IEEE JSSC, vol. 37, No. 11, pp. 1510-1522 (2002); T. Shino, N. Kusunoki, T. Higashi, T. Ohsawa, K. Fujita, K. Hatsuda, N. Ikumi, F. Matsuoka, Y. Kajitani, R. Fukuda, Y. Watanabe, Y. Minami, A. Sakamoto, J. Nishimura, H. Nakajima, M. Morikado, K. Inch, T. Hamamoto, A. Nitayama: “Floating Body RAM Technology and its Scalability to 32nm Node and Beyond”, IEEE IEDM (2006); and E. Yoshida and T. Tanaka: “A Design of a Capacitorless 1T-DRAM Cell Using Gate-Induced Drain-Leakage (GIDL) Current for Low-Power and High-Speed Embedded Memory”, IEEE IEDM (2003)).

FIGS. 7A to 7D illustrate a write operation of the DRAM memory cell. FIG. 7A illustrates a “1” write state. A memory cell 110a is formed on a silicon on insulator (SOI) substrate 100 and is constituted by a source N⁺ layer 103 (hereinafter, a semiconductor region containing donor impurities at high concentration will be referred to as an “N⁺ layer”) connected to a source line SL, a drain N⁺ layer 104 connected to a bit line BL, a gate conductive layer 105 connected to a word line WL, and a floating body 102 of a MOS transistor. The DRAM memory cell does not include a capacitor and is constituted by the single MOS transistor. A SiO₂ layer 101 of the SOI substrate 100 is immediately under the floating body 102 and is in contact with the floating body 102. To write “1” in the memory cell 110a constituted by the single MOS transistor, the MOS transistor is operated in a saturation region. That is, an electron channel 107 extending from the source N⁺ layer 103 has a pinch-off point 108 and does not reach the drain N⁺ layer 104 connected to the bit line BL. When the MOS transistor is operated such that the bit line BL connected to the drain N⁺ layer 104 and the word line WL connected to the gate conductive layer 105 are both at a high voltage and that the gate voltage is about ½ of the drain voltage, the electric field strength becomes maximum at the pinch-off point 108 near the drain N⁺ layer 104. As a result, accelerated electrons flowing from the source N⁺ layer 103 toward the drain N⁺ layer 104 collide with a Si lattice, and the kinetic energy lost at the time generates electron-hole pairs. Most of the generated electrons (not illustrated) reach the drain N⁺ layer 104. A very small portion of the electrons, which is very hot, jumps over a gate oxide film 109 and reaches the gate conductive layer 105. Positive holes 106 generated simultaneously charge the floating body 102. In this case, the generated positive holes 106 contribute as an increment of a majority carrier because the floating body 102 is made of P-type Si. When the floating body 102 is filled with the generated positive holes 106 and the voltage of the floating body 102 becomes higher than that of the source N⁺ layer 103 by Vb or more, positive holes further generated are discharged to the source N⁺ layer 103. Here, Vb is a built-in voltage of the PN junction between the source N⁺ layer 103 and the floating body 102 as a P layer, and is about 0.7 V. FIG. 7B illustrates a state in which the floating body 102 is charged to saturation with the generated positive holes 106.

Next, a “0” write operation of a memory cell 110 will be described with reference to FIG. 7C. For a selected common word line WL, there are randomly a memory cell 110a for writing “1” and a memory cell 110b for writing “0”. FIG. 7C illustrates a state of rewriting from a “1” write state to a “0” write state. To write “0”, the voltage of the bit line BL is negatively biased and the PN junction between the drain N⁺ layer 104 and the floating body 102 as a P layer is forward biased. As a result, the positive holes 106 generated in the floating body 102 in advance in the previous cycle flow into the drain N⁺ layer 104 connected to the bit line BL. Upon completion of the write operation, two memory cell states are obtained: the memory cell 110a filled with the generated positive holes 106 (FIG. 7B); and the memory cell 110b from which the generated positive holes 106 have been discharged (FIG. 7C). The floating body 102 of the memory cell 110a filled with the positive holes 106 has a potential higher than that of the floating body 102 having no generated positive holes. Thus, a threshold voltage of the memory cell 110a is lower than a threshold voltage of the memory cell 110b. This state is illustrated in FIG. 7D.

Next, a problem in the operation of the memory cell constituted by the single MOS transistor will be described with reference to FIGS. 8A and 8B. As illustrated in FIG. 8A, a capacitance C_{FB} of the floating body 102 is the sum of a capacitance C_{WL} between the gate connected to the word line and the floating body 102, a junction capacitance C_{SL} of the PN junction between the source N⁺ layer 103 connected to the source line and the floating body 102, and a junction capacitance C_{BL} of the PN junction between the drain N⁺ layer 104 connected to the bit line and the floating body 102, and is expressed as follows.

$${\text{C}}_{\text{FB}} {\text{= C}}_{\text{WL}} {\text{+ C}}_{\text{BL}} {\text{+ C}}_{\text{SL}} \qquad \text{(1)}$$

Thus, if a word line voltage V_{WL} oscillates at the time of writing, the oscillation affects the voltage of the floating body 102 serving as a storage node (contact point) of the memory cell. This state is illustrated in FIG. 8B. In accordance with an increase in the word line voltage V_{WL} from 0 V to V_{progWL} at the time of writing, a voltage V_{FB} of the floating body 102 increases from a voltage V_{FB1} in an initial state before the word line voltage changes to a voltage V_{FB2} due to capacitive coupling with the word line. The amount of voltage change ΔV_{FB} is expressed as follows.

$$\text{Δ} {\text{V}}_{\text{FB}} {\text{= V}}_{\text{FB1}} - {\text{V}}_{\text{FB2}}$$

$$\text{=} {\text{C}}_{\text{WL}} / \left({\text{C}}_{\text{WL}} {\text{+ C}}_{\text{BL}} {\text{+ C}}_{\text{SL}}\right) \times {\text{V}}_{\text{ProgWL}} \qquad \text{(2)}$$

Here, the following equation holds, in which β represents a coupling ratio.

$$\text{β} \text{=} {\text{C}}_{\text{WL}} / \left({\text{C}}_{\text{WL}} {\text{+ C}}_{\text{BL}} {\text{+ C}}_{\text{SL}}\right) \qquad \text{(3)}$$

In such a memory cell, C_{WL} has a high contribution ratio, for example, C_{WL}: C_{BL}: C_{SL} = 8:1:1. In this case, β equals 0.8. When the word line changes, for example, from 5 V at the time of writing to 0 V after the end of writing, the capacitive coupling between the word line and the floating body 102 causes the floating body 102 to be subjected to oscillation noise of 5 V × β = 4 V. This involves a problem that a sufficient potential difference margin is not provided between the “1” potential and the “0” potential of the floating body 102 at the time of writing.

FIGS. 9A to 9C illustrate a read operation. FIG. 9A illustrates a “1” write state, and FIG. 9B illustrates a “0” write state. Actually, however, even if Vb is written in the floating body 102 by “1” writing, the floating body 102 is lowered to a negative bias when the word line returns to 0 V upon completion of writing. When “0” is written, the floating body 102 is further negatively biased, and thus it is impossible to provide a sufficiently large potential difference margin between “1” and “0” at the time of writing. The small operation margin is a major problem of the DRAM memory cell. In addition, there is an issue of increasing the density of the DRAM memory cell.

### SUMMARY OF THE INVENTION

A capacitorless single-transistor DRAM(gain cell) serving as a memory device including an SGT has a problem that oscillation of the potential of the word line at the time of reading or writing data is directly transmitted as noise to a floating SGT body because the capacitive coupling between the word line and the SGT body is large. This results in a problem of erroneous reading or erroneous rewriting of stored data, and difficulty in putting a capacitorless single-transistor DRAM (gain cell) into practical use. It is necessary to increase the density of DRAMmemory cells in addition to solve the above problems.

To solve the above problem, a method for manufacturing a memory device including a pillar-shaped semiconductor element according to the present invention is a method for manufacturing a memory device configured to control voltages to be applied to a first gate conductor layer, a second gate conductor layer, a third gate conductor layer, a first impurity region, and second impurity regions to perform a data write operation, a data read operation, and a data erase operation, the method including the steps of:
forming a first semiconductor pillar, a second semiconductor pillar, a third semiconductor pillar, and a fourth semiconductor pillar that stand on a substrate in a vertical direction, the first semiconductor pillar and the second semiconductor pillar having respective midpoints on a first line in plan view and being disposed adjacent to each other, the third semiconductor pillar and the fourth semiconductor pillar having respective midpoints on a second line parallel to the first line in plan view and being disposed adjacent to each other;
forming first gate insulating layers and the first gate conductor layer, the first gate insulating layers each surrounding a corresponding one of the first to fourth semiconductor pillars, the first gate conductor layer surrounding the first gate insulating layers;
forming second gate insulating layers adjacent to the first gate insulating layers in the vertical direction and each surrounding a side surface of a corresponding one of the first to fourth semiconductor pillars;
forming the second gate conductor layer and the third gate conductor layer that surround the respective second gate insulating layers, the second gate conductor layer being continuous between the first semiconductor pillar and the second semiconductor pillar on the first line and being isolated from the first gate conductor layer in the vertical direction, the third gate conductor layer being continuous between the third semiconductor pillar and the fourth semiconductor pillar on the second line and being isolated from the first gate conductor layer in the vertical direction;
before or after the forming of the first to fourth semiconductor pillars, forming the first impurity region connected to bottom portions of the first to fourth semiconductor pillars;
before or after the forming of the first to fourth semiconductor pillars, forming the second impurity regions each disposed at a top portion of a corresponding one of the first to fourth semiconductor pillars; and
forming a first wiring conductor layer and a second wiring conductor layer, the first wiring conductor layer being connected to the second impurity regions at the top portions of the first semiconductor pillar and the third semiconductor pillar, the second wiring conductor layer being connected to the second impurity regions at the top portions of the second semiconductor pillar and the fourth semiconductor pillar (first invention).

In the first invention,
a first length is smaller than a second length in plan view, the first length being a length between two opposed points among intersection points between the first line and two outer periphery lines of the first gate insulating layers surrounding the first semiconductor pillar and the second semiconductor pillar, the second length being a length between two opposed points among intersection points between a third line passing through the midpoint of the first semiconductor pillar and orthogonal to the first line and two outer periphery lines of the second gate insulating layers surrounding the first semiconductor pillar and the third semiconductor pillar,
the second length is larger than twice a third length in plan view, the third length being a thickness of the first gate conductor layer located on the third line and surrounding the first semiconductor pillar, and
the first length is smaller than twice the third length in plan view (second invention).

In the first invention, the method further includes the steps of:
after the forming of the second gate insulating layers, forming a first conductor layer on outer periphery portions of the second gate insulating layers, the first conductor layer having an upper surface position located near lower ends of the second impurity regions in the vertical direction;
forming first mask material layers, a second mask material layer, and a third mask material layer, the first mask material layers each being disposed on the top portion of a corresponding one of the first to fourth semiconductor pillars, the second mask material layer being continuous between the first semiconductor pillar and the second semiconductor pillar, the third mask material layer being continuous between the third semiconductor pillar and the fourth semiconductor pillar, the second mask material layer and the third mask material layer being disposed on the first conductor layer, surrounding side surfaces of the second impurity regions, and being separated from each other; and
etching the first conductor layer by using the first mask material layers, the second mask material layer, and the third mask material layer as a mask, to form the second gate conductor layer and the third gate conductor layer (third invention).

In the third invention, the method further includes the steps of:
after the forming of the second gate insulating layers, forming a second conductor layer on outer periphery portions of the second gate insulating layers, the second conductor layer having an upper surface position corresponding to an upper end of the second gate conductor layer in the vertical direction;
forming a first insulating layer on the second conductor layer;
forming fourth mask material layers disposed on the first insulating layer, surrounding the respective first mask material layers and the respective second impurity regions, and separated from each other;
forming a fifth mask material layer and a sixth mask material layer that are disposed on the fourth mask material layers, the fifth mask material layer at least partially overlapping the first semiconductor pillar and the second semiconductor pillar in plan view, the sixth mask material layer at least partially overlapping the third semiconductor pillar and the fourth semiconductor pillar in plan view; and
etching the second conductor layer by using seventh mask material layers each disposed on the top portion of a corresponding one of the first to fourth semiconductor pillars, the fifth mask material layer, and the sixth mask material layer as a mask, to form the second gate conductor layer and the third gate conductor layer (fourth invention).

In the first invention,
the memory device is formed such that a wiring line connected to the first impurity region is a source line, a wiring line connected to the second impurity regions is a bit line, one of a wiring line connected to the first gate conductor layer and a wiring line connected to the second gate conductor layer and the third gate conductor layer is a word line, and an other of the wiring line connected to the first gate conductor layer and the wiring line connected to the second gate conductor layer and the third gate conductor layer is a first drive control line, and
the memory device is configured to perform the data write operation, the data read operation, and the data erase operation by applying voltages to the source line, the bit line, the first drive control line, and the word line (fifth invention).

In the first invention,
the memory device is formed such that a first gate capacitance between the first gate conductor layer and the first semiconductor pillar is larger than a second gate capacitance between the second gate conductor layer and the first semiconductor pillar (sixth invention).

In the first invention,
a first hole is formed between the second gate conductor layer and the third gate conductor layer in plan view (seventh invention).

In the first invention,
a second hole is formed between the first wiring conductor layer and the second wiring conductor layer (eighth invention).

In the third invention, the method further includes the steps of:
etching the first conductor layer by using the first mask material layers, the second mask material layer, and the third mask material layer as a mask, to form the second gate conductor layer and the third gate conductor layer;
forming a second insulating layer surrounding side surfaces of the second gate conductor layer, the third gate conductor layer, the second mask material layer, and the third mask material layer;
etching the first mask material layers on the top portions of the first to fourth semiconductor pillars by using the second mask material layer, the third mask material layer, and the second insulating layer as a mask, to form first contact holes each disposed on a corresponding one of the second impurity regions; and
forming the first wiring conductor layer and the second wiring conductor layer, the first wiring conductor layer being connected to the second impurity regions at the top portions of the first semiconductor pillar and the third semiconductor pillar through corresponding first contact holes of the first contact holes, the second wiring conductor layer being connected to the second impurity regions at the top portions of the second semiconductor pillar and the fourth semiconductor pillar through corresponding first contact holes of the first contact holes (ninth invention).

In the fourth invention, the method further includes the steps of:
etching the first conductor layer by using the seventh mask material layers, the second mask material layer, and the third mask material layer as a mask, to form the second gate conductor layer and the third gate conductor layer;
forming a third insulating layer surrounding side surfaces of the second gate conductor layer, the third gate conductor layer, the second mask material layer, and the third mask material layer;
etching the seventh mask material layers on the top portions of the first to fourth semiconductor pillars by using the second mask material layer, the third mask material layer, and the third insulating layer as a mask, to form second contact holes each disposed on a corresponding one of the second impurity regions; and
forming the first wiring conductor layer and the second wiring conductor layer, the first wiring conductor layer being connected to the second impurity regions at the top portions of the first semiconductor pillar and the third semiconductor pillar through corresponding second contact holes of the second contact holes, the second wiring conductor layer being connected to the second impurity regions at the top portions of the second semiconductor pillar and the fourth semiconductor pillar through corresponding second contact holes of the second contact holes (tenth invention).

In the fourth invention, the method further includes the steps of:
etching the first conductor layer by using the seventh mask material layers, the fourth mask material layers, the fifth mask material layer, and the sixth mask material layer as a mask, to form the second gate conductor layer and the third gate conductor layer;
forming a fourth insulating layer surrounding side surfaces of the second gate conductor layer, the third gate conductor layer, and the fourth mask material layers;
etching the seventh mask material layers on the top portions of the first to fourth semiconductor pillars by using the fourth insulating layer and the fourth mask material layers as a mask, to form third contact holes each disposed on a corresponding one of the second impurity regions; and
forming the first wiring conductor layer and the second wiring conductor layer, the first wiring conductor layer being connected to the second impurity regions at the top portions of the first semiconductor pillar and the third semiconductor pillar through corresponding third contact holes of the third contact holes, the second wiring conductor layer being connected to the second impurity regions at the top portions of the second semiconductor pillar and the fourth semiconductor pillar through corresponding third contact holes of the third contact holes (eleventh invention).

In the first invention,
the second gate insulating layers are formed so as to surround the side surfaces of the first to fourth semiconductor pillars and be connected onto the first gate conductor layer such that the first gate conductor layer is insulated from the second gate conductor layer and the third gate conductor layer in the vertical direction (twelfth invention).

In the first invention,
the first to fourth semiconductor pillars, the first gate conductor layer, the second gate conductor layer, the third gate conductor layer, the first impurity region, and the second impurity regions are formed so as to perform the data write operation and the data erase operation, the data write operation being an operation of holding, in an inside of any or all of the first to fourth semiconductor pillars, a positive hole group generated by an impact ionization phenomenon or a gate-induced drain-leakage current, the data erase operation being an operation of discharging the positive hole group from the inside of any or all of the first to fourth semiconductor pillars by controlling voltages to be applied to the first to third gate conductor layers, the first impurity region, and the second impurity regions (thirteenth invention).

In the first invention, the method further includes the steps of:
forming third gate insulating layers each surrounding a corresponding one of the first to fourth semiconductor pillars at upper portions of the second gate conductor layer and the third gate conductor layer in the vertical direction; and
forming a fourth gate conductor layer and a fifth gate conductor layer, the fourth gate conductor layer surrounding the third gate insulating layers and being continuous between the first semiconductor pillar and the second semiconductor pillar on the first line, the fifth gate conductor layer being continuous between the third semiconductor pillar and the fourth semiconductor pillar on the second line (fourteenth invention).

In the first invention, the forming of the first gate conductor layer includes forming the first gate conductor layer divided into a sixth gate conductor layer and a seventh gate conductor layer, the sixth gate conductor layer being continuous between the first semiconductor pillar and the second semiconductor pillar on the first line, the seventh gate conductor layer being continuous between the third semiconductor pillar and the fourth semiconductor pillar on the second line. (fifteenth invention).

### BRIEF DESCRIPTION OF THE DRAWINGS

FIG. 1 is a structural diagram of a memory device including an SGT according to a first embodiment;

FIGS. 2A, 2B, and 2C are diagrams for describing an erase operation mechanism of the memory device including an SGT according to the first embodiment;

FIGS. 3A, 3B, and 3C are diagrams for describing a write operation mechanism of the memory device including an SGT according to the first embodiment;

FIGS. 4AA, 4AB, and 4AC are diagrams for describing a read operation mechanism of the memory device including an SGT according to the first embodiment;

FIGS. 4BD, 4BE, 4BF, and 4BG are diagrams for describing a read operation mechanism of the memory device including an SGT according to the first embodiment;

FIGS. 5AA, 5AB, and 5AC are diagrams for describing a method for manufacturing the memory device including an SGT according to the first embodiment;

FIGS. 5BA, 5BB, and 5BC are diagrams for describing the method for manufacturing the memory device including an SGT according to the first embodiment;

FIGS. 5CA, 5CB, and 5CC are diagrams for describing the method for manufacturing the memory device including an SGT according to the first embodiment;

FIGS. 5DA, 5DB, and 5DC are diagrams for describing the method for manufacturing the memory device including an SGT according to the first embodiment;

FIGS. 5EA, 5EB, and 5EC are diagrams for describing the method for manufacturing the memory device including an SGT according to the first embodiment;

FIGS. 5FA, 5FB, 5FC, and 5FD are diagrams for describing the method for manufacturing the memory device including an SGT according to the first embodiment;

FIGS. 5GA, 5GB, 5GC, and 5GD are diagrams for describing the method for manufacturing the memory device including an SGT according to the first embodiment;

FIGS. 5HA, 5HB, and 5HC are diagrams for describing the method for manufacturing the memory device including an SGT according to the first embodiment;

FIG. 5I is a schematic structural diagram of the memory device including an SGT according to the first embodiment;

FIGS. 6AA, 6AB, and 6AC are diagrams for describing a method for manufacturing a memory device including an SGT according to a second embodiment;

FIGS. 6BA, 6BB, and 6BC are diagrams for describing the method for manufacturing the memory device including an SGT according to the second embodiment;

FIGS. 6CA, 6CB, and 6CC are diagrams for describing the method for manufacturing the memory device including an SGT according to the second embodiment;

FIGS. 6DA, 6DB, and 6DC are diagrams for describing the method for manufacturing the memory device including an SGT according to the second embodiment;

FIGS. 6EA, 6EB, and 6EC are diagrams for describing the method for manufacturing the memory device including an SGT according to the second embodiment;

FIG. 6F is a schematic structural diagram of the memory device including an SGT according to the second embodiment;

FIGS. 7A, 7B, 7C, and 7D are diagrams for describing a write operation of a capacitorless DRAM memory cell according to the related art;

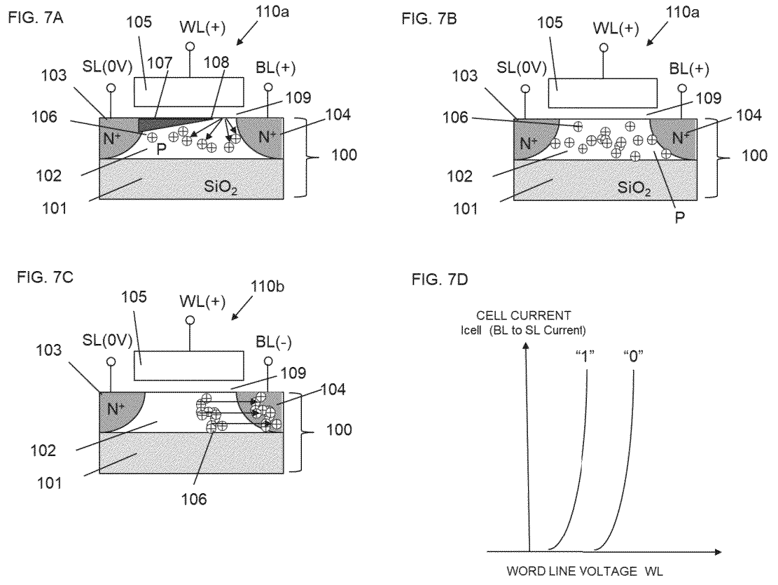

FIGS. 8A and 8B are diagrams for describing a problem in the operation of the capacitorless DRAM memory cell according to the related art; and

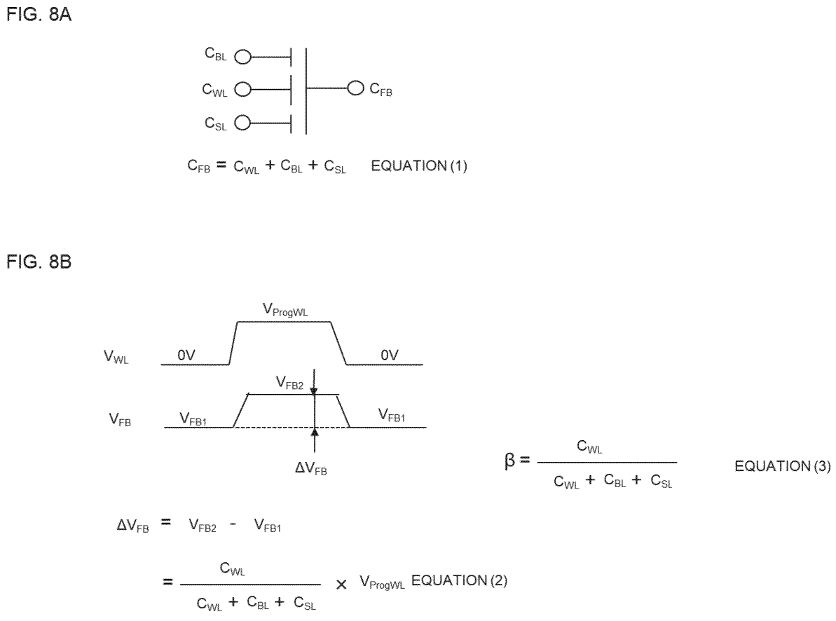

FIGS. 9A, 9B, and 9C are diagrams for describing a read operation of the capacitorless DRAM memory cell according to the related art.

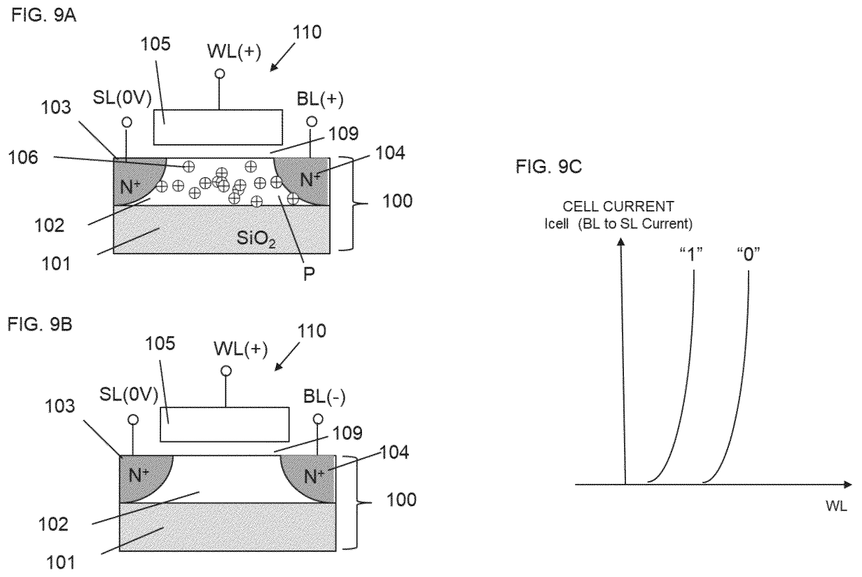

### DESCRIPTION OF THE PREFERRED EMBODIMENTS

Hereinafter, a method for manufacturing a memory device including a semiconductor element (hereinafter referred to as a dynamic flash memory) according to the present invention will be described with reference to the drawings.

### First Embodiment

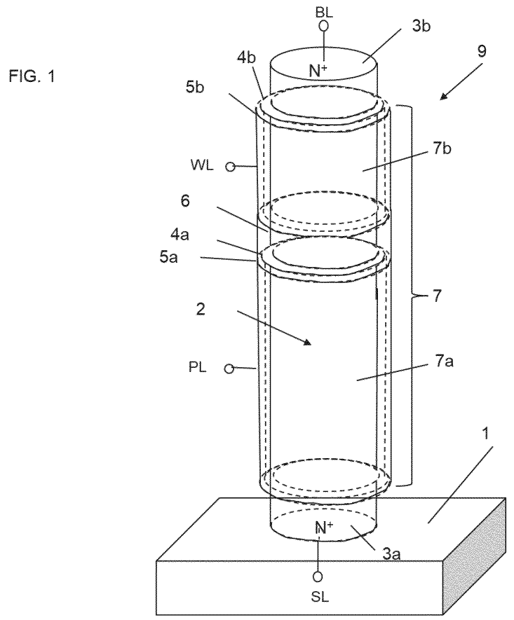

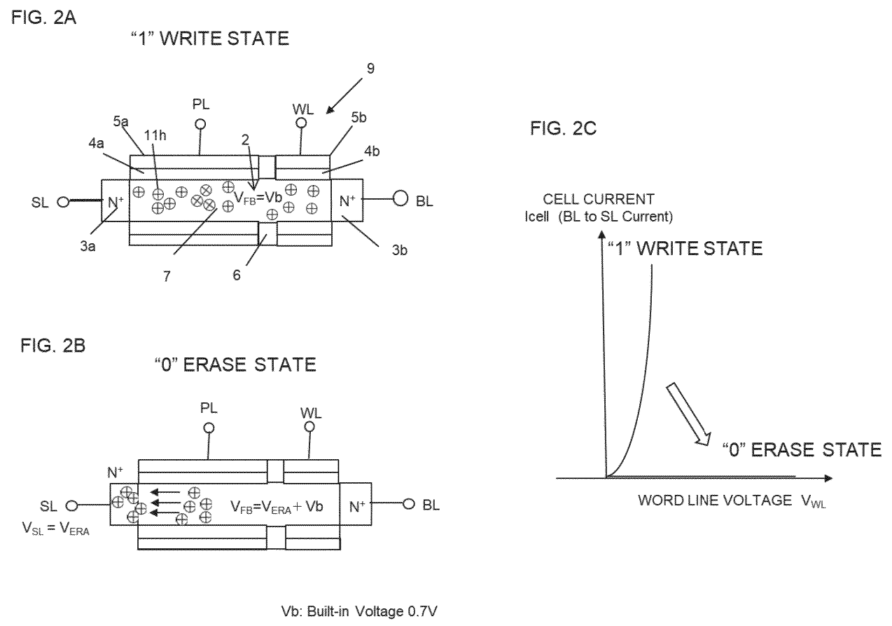

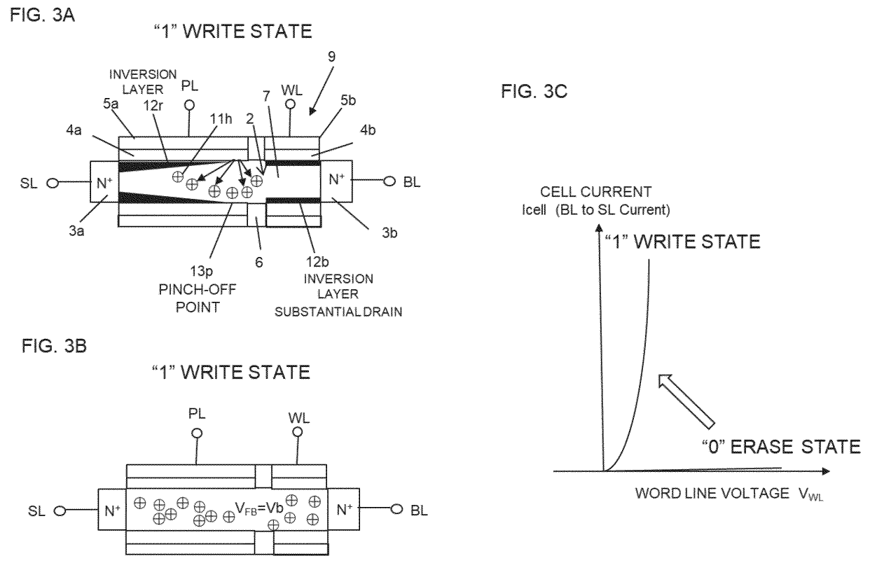

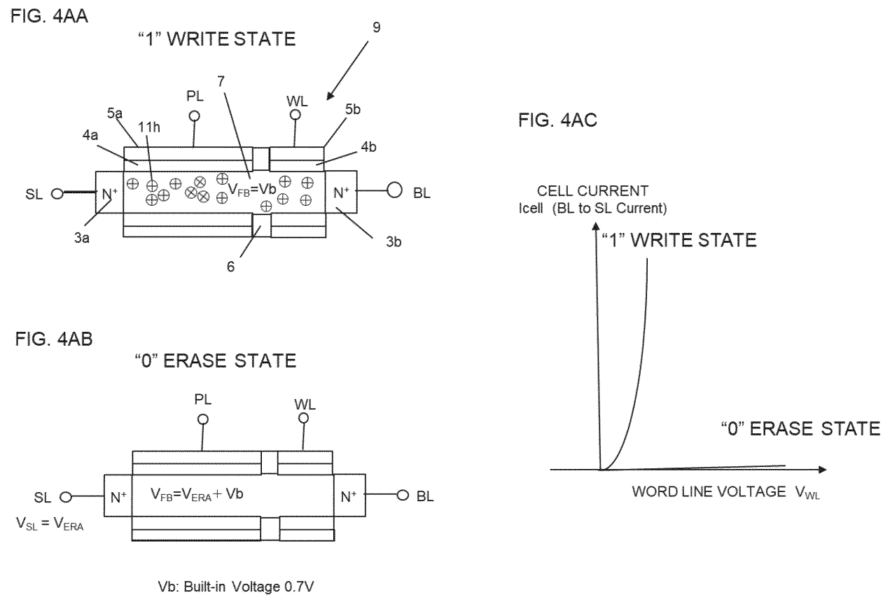

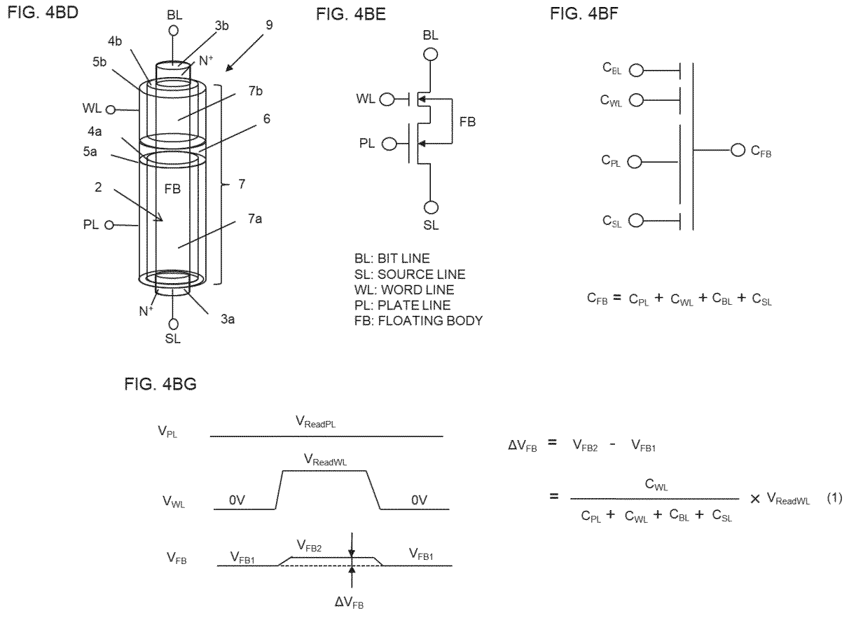

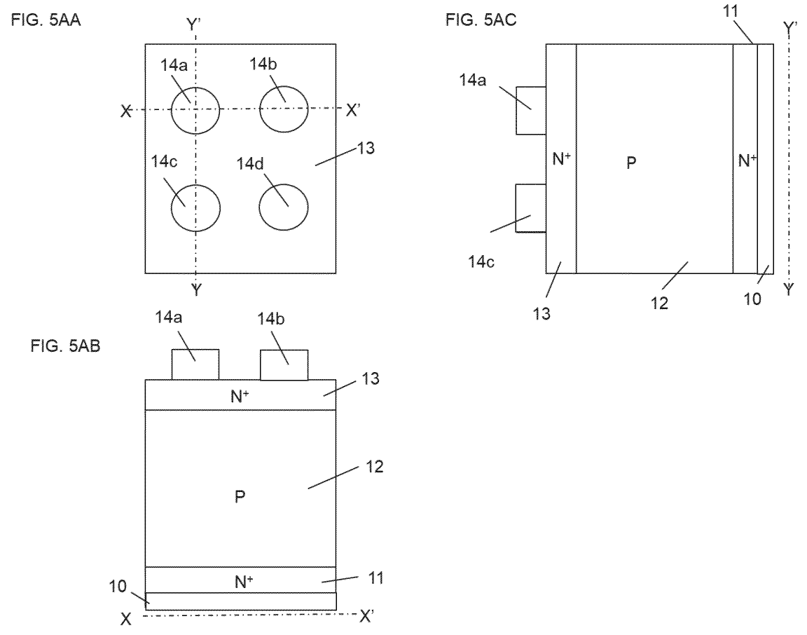

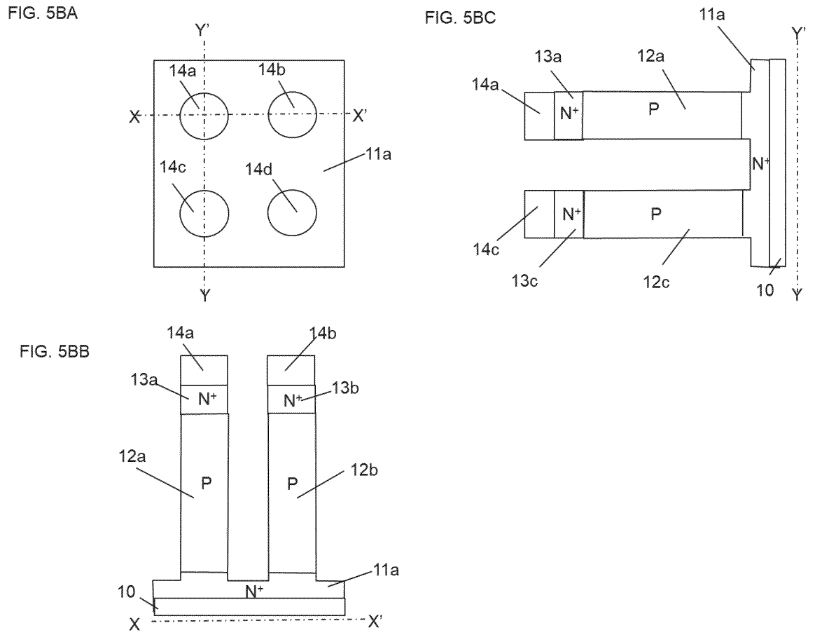

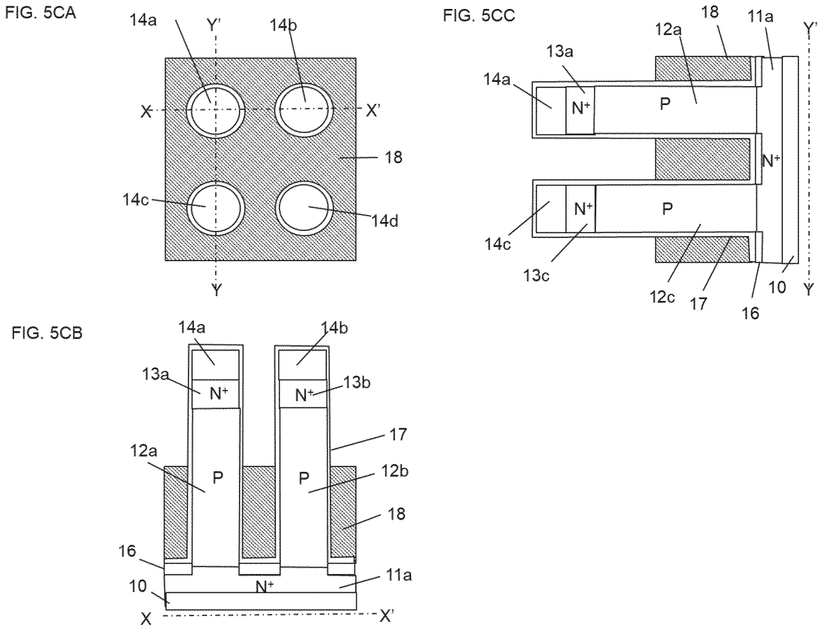

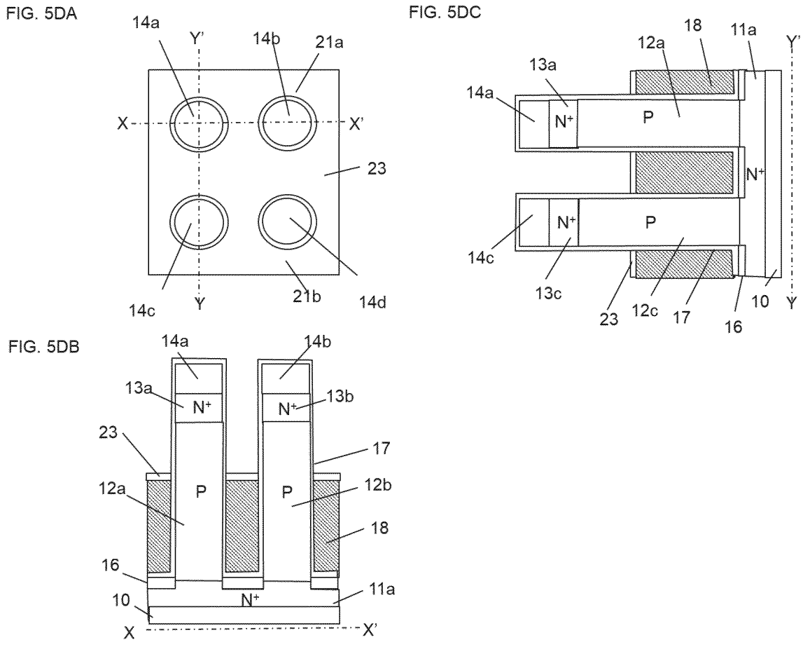

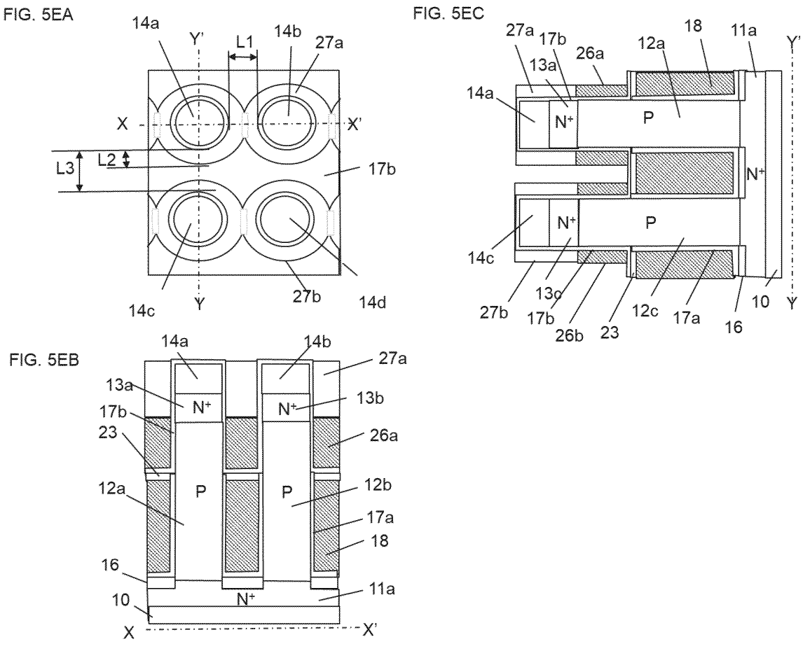

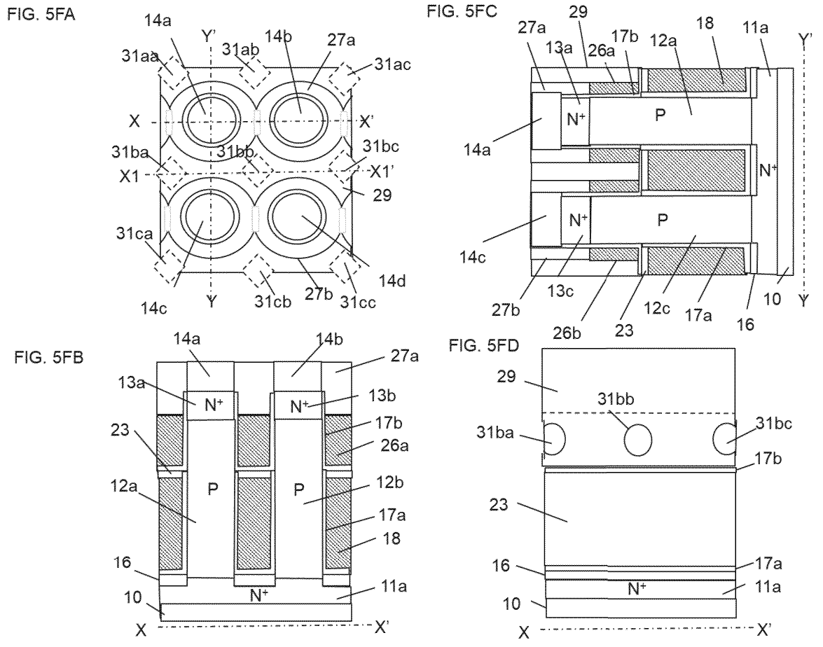

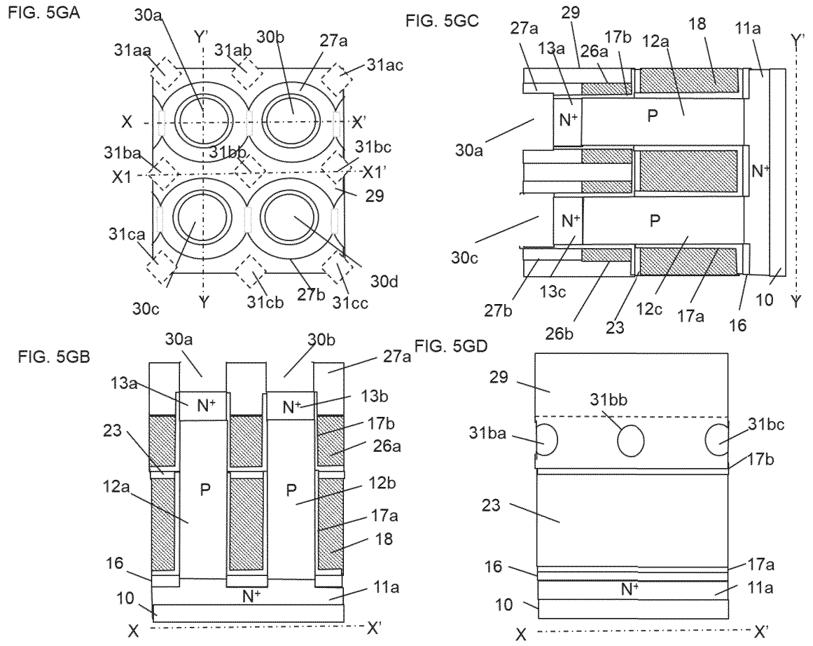

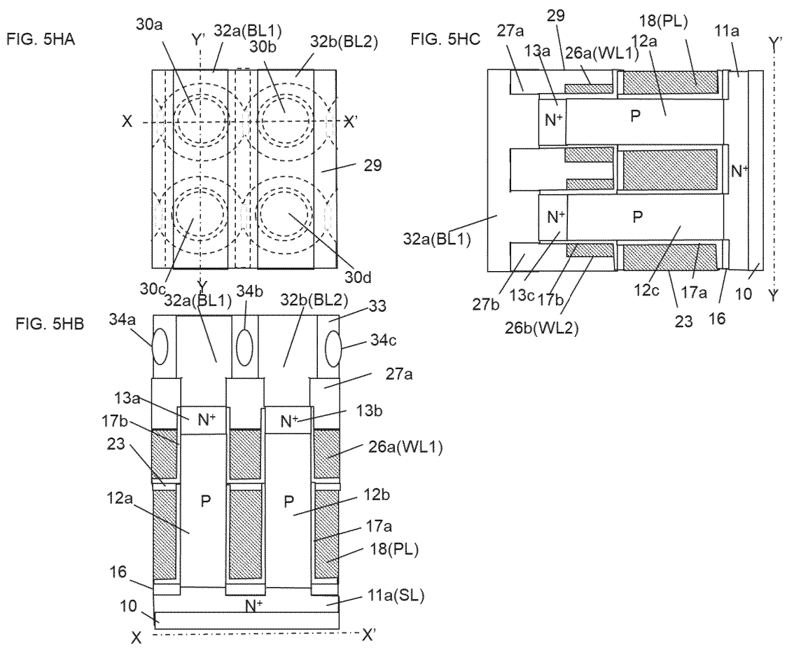

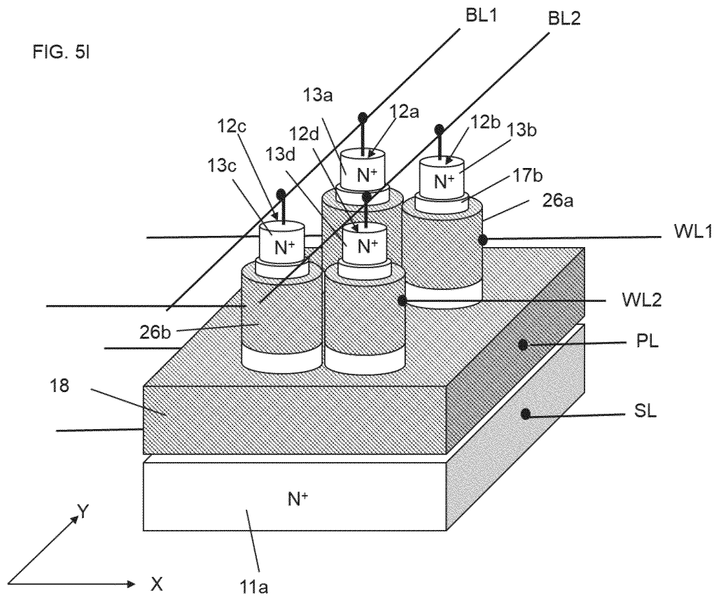

The structure, operation mechanism, and manufacturing method of a dynamic flash memory cell according to a first embodiment of the present invention will be described with reference to FIG. 1 to FIG. 5I. The structure of the dynamic flash memory cell will be described with reference to FIG. 1. A data erase mechanism will be described with reference to FIGS. 2A to 2C, a data write mechanism will be described with reference to FIGS. 3A to 3C, and a data read mechanism will be described with reference to FIG. 4AA to 4BG. A method for manufacturing a dynamic flash memory will be described with reference to FIG. 5AA to 5I.

FIG. 1 illustrates the structure of the dynamic flash memory cell according to the first embodiment of the present invention. At lower and upper positions in a silicon semiconductor pillar 2 (hereinafter a silicon semiconductor pillar will be referred to as a “Si pillar”) having a conductivity type of P type or i type (intrinsic type) and formed on a substrate 1, an N⁺ layer 3a and an N⁺ layer 3b are formed, one of which serves as a source and the other of which servers as a drain. The portion of the Si pillar 2 between the N⁺ layers 3a and 3b serving as the source and drain is a channel region 7. A first gate insulating layer 4a and a second gate insulating layer 4b are formed so as to surround the channel region 7. The first gate insulating layer 4a and the second gate insulating layer 4b are respectively in contact with or close to the N⁺ layers 3a and 3b serving as the source and drain. A first gate conductor layer 5a and a second gate conductor layer 5b are formed so as to surround the first gate insulating layer 4a and the second gate insulating layer 4b, respectively. The first gate conductor layer 5a and the second gate conductor layer 5b are isolated from each other by an insulating layer 6. The channel region 7 in the portion of the Si pillar 2 between the N⁺ layers 3a and 3b is composed of a first channel region 7a surrounded by the first gate insulating layer 4a, and a second channel region 7b surrounded by the second gate insulating layer 4b. Accordingly, a dynamic flash memory cell 9 composed of the N⁺ layers 3a and 3b serving as the source and drain, the channel region 7, the first gate insulating layer 4a, the second gate insulating layer 4b, the first gate conductor layer 5a, and the second gate conductor layer 5b is formed. The N⁺ layer 3a serving as the source is connected to a source line SL, the N⁺ layer 3b serving as the drain is connected to a bit line BL, the first gate conductor layer 5a is connected to a plate line PL, and the second gate conductor layer 5b is connected to a word line WL. In a desired structure, the gate capacitance of the first gate conductor layer 5a connected to the plate line PL is larger than the gate capacitance of the second gate conductor layer 5b connected to the word line WL.

In FIG. 1, the gate length of the first gate conductor layer 5a is made larger than the gate length of the second gate conductor layer 5b so that the gate capacitance of the first gate conductor layer 5a connected to the plate line PL is larger than the gate capacitance of the second gate conductor layer 5b connected to the word line WL. Alternatively, instead of making the gate length of the first gate conductor layer 5a larger than the gate length of the second gate conductor layer 5b, the gate insulating film of the first gate insulating layer 4a may be made thinner than the gate insulating film of the second gate insulating layer 4b by changing the film thicknesses of the respective gate insulating layers. The permittivity of the gate insulating film of the first gate insulating layer 4a may be made higher than the permittivity of the gate insulating film of the second gate insulating layer 4b by changing the permittivities of the materials of the respective gate insulating layers. The gate capacitance of the first gate conductor layer 5a connected to the plate line PL may be made larger than the gate capacitance of the second gate conductor layer 5b connected to the word line WL by combining the lengths of the gate conductor layers 5a and 5b and the film thicknesses or permittivities of the gate insulating layers 4a and 4b.

A data erase operation mechanism of the dynamic flash memory cell according to the first embodiment of the present invention will be described with reference to FIGS. 2A to 2C. The channel region 7 between the N⁺ layers 3a and 3b is electrically isolated from the substrate 1 and serves as a floating body. FIG. 2A illustrates a state in which a positive hole group 11h generated by impact ionization in the previous cycle is stored in the channel region 7 before a data erase operation. As illustrated in FIG. 2B, the voltage of the source line SL is set to a negative voltage V_{ERA} at the time of the data erase operation. Here, V_{ERA} is –3 V, for example. As a result, the PN junction between the channel region 7 and the N⁺ layer 3a serving as the source connected to the source line SL is forward biased, regardless of the value of an initial potential of the channel region 7. As a result, the positive hole group 11h generated by impact ionization in the previous cycle and stored in the channel region 7 is drawn into the N⁺ layer 3a serving as the source, and a potential V_{FB} of the channel region 7 becomes V_{ERA} + Vb. Here, Vb is a built-in voltage of the PN junction and is about 0.7 V. Thus, when V_{ERA} = –3 V holds, the potential of the channel region 7 is –2.3 V. This value corresponds to the potential state of the channel region 7 in an erase state. Thus, when the potential of the channel region 7 of the floating body becomes a negative voltage, the threshold voltage of the N-channel MOS transistor of the dynamic flash memory cell 9 increases due to a substrate bias effect. Accordingly, the threshold voltage of the second gate conductor layer 5b connected to the word line WL increases as illustrated in FIG. 2C. The data erase state in the channel region 7 corresponds to logical storage data “0”. In data reading, the voltage applied to the first gate conductor layer 5a connected to the plate line PL is set to be higher than the threshold voltage at the time of logical storage data “1” and lower than the threshold voltage at the time of logical storage data “0”, and thereby a characteristic is obtained in which no current flows even if the voltage of the word line WL is increased in reading of logical storage data “0”. The above-described conditions of the voltages applied to the bit line BL, the source line SL, the word line WL, and the plate line PL are examples for performing a data erase operation, and other operation conditions for performing the data erase operation may be used. For example, the data erase operation may be performed with a voltage difference being applied between the bit line BL and the source line SL.

FIGS. 3A to 3C illustrate a data write operation of the dynamic flash memory cell according to the first embodiment of the present invention. As illustrated in FIG. 3A, for example, 0 V is input to the N⁺ layer 3a connected to the source line SL, for example, 3 V is input to the N⁺ layer 3b connected to the bit line BL, for example, 2 V is input to the first gate conductor layer 5a connected to the plate line PL, and for example, 5 V is input to the second gate conductor layer 5b connected to the word line WL. As a result, as illustrated in FIG. 3A, an inversion layer 12r is formed on an inner side from the first gate conductor layer 5a connected to the plate line PL, and a first N-channel MOS transistor region formed of the first channel region 7a surrounded by the first gate conductor layer 5a is operated in a saturation region. As a result, a pinch-off point 13p is present in the inversion layer 12r on an inner side from the first gate conductor layer 5a connected to the plate line PL. On the other hand, a second N-channel MOS transistor region including the second gate conductor layer 5b connected to the word line WL is operated in a linear region. As a result, a pinch-off point is absent on an inner side from the second gate conductor layer 5b connected to the word line WL, and an inversion layer 12b is formed over the entire surface. The inversion layer 12b formed over the entire surface on the inner side from the second gate conductor layer 5b connected to the word line WL substantially functions as the drain of the second N-channel MOS transistor region including the second gate conductor layer 5b. As a result, the electric field becomes maximum in the boundary region of the channel region 7 between the first N-channel MOS transistor region including the first gate conductor layer 5a and the second N-channel MOS transistor region including the second gate conductor layer 5b that are connected in series, and an impact ionization phenomenon occurs in this region. This region is a region on the source side when viewed from the second N-channel MOS transistor region including the second gate conductor layer 5b connected to the word line WL, and thus this phenomenon is referred to as a source-side impact ionization phenomenon. The source-side impact ionization phenomenon causes electrons to flow from the N⁺ layer 3a connected to the source line SL toward the N⁺ layer 3b connected to the bit line BL. Accelerated electrons collide with lattice Si atoms, and the kinetic energy thereof generates electron-hole pairs. Some of the generated electrons flow to the first gate conductor layer 5a and the second gate conductor layer 5b, but most of the electrons flow to the N⁺ layer 3b connected to the bit line BL. In writing of “1”, electron-hole pairs may be generated by using a gate-induced drain-leakage (GIDL) current (see E. Yoshida and T. Tanaka: “A Capacitorless 1T-DRAM Technology Using Gate-Induced Drain-Leakage (GIDL) Current for Low-Power and High-Speed Embedded Memory”, IEEE Transactions on Electron Devices, Vol. 53, No. 4, pp. 692-697, April 2006), and a floating body FB may be filled with the generated positive hole group.

As illustrated in FIG. 3B, the generated positive hole group 11h is a majority carrier in the channel region 7 and charges the channel region 7 to a positive bias. The N⁺ layer 3a connected to the source line SL is at 0 V, and thus the channel region 7 is charged to the built-in voltage Vb (about 0.7 V) of the PN junction between the N⁺ layer 3a connected to the source line SL and the channel region 7. Upon the channel region 7 being charged to a positive bias, the threshold voltages of the first N-channel MOS transistor region and the second N-channel MOS transistor region are decreased by a substrate bias effect. Accordingly, as illustrated in FIG. 3C, the threshold voltage of the N-channel MOS transistor of the second channel region 7b connected to the word line WL decreases. The data write state of the channel region 7 is assigned to logical storage data “1”.

At the time of the write operation, in a second boundary region between a first impurity layer and a first channel semiconductor layer or in a third boundary region between a second impurity layer and a second channel semiconductor layer, electron-hole pairs may be generated by an impact ionization phenomenon or a GIDL current, and the channel region 7 may be charged with the generated positive hole group 11h. The above-described conditions of the voltages applied to the bit line BL, the source line SL, the word line WL, and the plate line PL are examples for performing a data write operation, and other operation conditions for performing the data write operation may be used.

A data read operation of the dynamic flash memory cell according to the first embodiment of the present invention and a memory cell structure related thereto will be described with reference to FIG. 4AA to 4AC and FIG. 4BD to 4BG. A data read operation of the dynamic flash memory cell will be described with reference to FIG. 4AA to 4AC. As illustrated in FIG. 4AA, upon the channel region 7 being charged to the built-in voltage Vb (about 0.7 V), the threshold voltage of the N-channel MOS transistor is decreased by a substrate bias effect. This state is assigned to logical storage data “1”. As illustrated in FIG. 4AB, when the memory block selected before writing is in an erase state “0” in advance, the channel region 7 is at a floating voltage V_{FB}, which is V_{ERA} + Vb. The write operation causes a write state “1” to be randomly stored. As a result, logical storage data of the logic “0” and “1” is generated for the word line WL. As illustrated in FIG. 4AC, reading is performed by a sense amplifier by using a difference between two threshold voltages for the word line WL. In a data read operation, the voltage applied to the first gate conductor layer 5a connected to the plate line PL is set to be higher than the threshold voltage at the time of logical storage data “1” and lower than the threshold voltage at the time of logical storage data “0”, and thereby a characteristic is obtained in which, as illustrated in FIG. 4AC, no current flows even if the voltage of the word line WL is increased in reading of logical storage data “0”. Alternatively, a data read operation may be performed by a bipolar operation.

With reference to FIG. 4BD to 4BG, a description will be given of the magnitude relationship between the gate capacitances of the first gate conductor layer 5a and the second gate conductor layer 5b at the time of a read operation of the dynamic flash memory cell according to the first embodiment of the present invention, and an operation related thereto. The gate capacitance of the second gate conductor layer 5b connected to the word line WL is desirably designed so as to be smaller than the gate capacitance of the first gate conductor layer 5a connected to the plate line PL. As illustrated in FIG. 4BD, the length in the vertical direction of the first gate conductor layer 5a connected to the plate line PL is made larger than the length in the vertical direction of the second gate conductor layer 5b connected to the word line WL so that the gate capacitance of the second gate conductor layer 5b connected to the word line WL is smaller than the gate capacitance of the first gate conductor layer 5a connected to the plate line PL. FIG. 4BE illustrates an equivalent circuit of one cell of the dynamic flash memory illustrated in FIG. 4BD. FIG. 4BF illustrates a coupling capacitance relationship of the dynamic flash memory. Here, C_{WL} is the capacitance of the second gate conductor layer 5b, C_{PL} is the capacitance of the first gate conductor layer 5a, C_{BL} is the capacitance of the PN junction between the N⁺ layer 3b serving as a drain and the second channel region 7b, and C_{SL} is the capacitance of the PN junction between the N⁺ layer 3a serving as a source and the first channel region 7a. As illustrated in FIG. 4BG, when the voltage of the word line WL oscillates, the operation affects the channel region 7 as noise. A potential variation ΔV_{FB} of the channel region 7 at this time is expressed as follows.

$$\text{Δ} {\text{V}}_{\text{FB}} \text{=} {\text{C}}_{\text{WL}} / \left({\text{C}}_{\text{PL}} {\text{+ C}}_{\text{WL}} {\text{+ C}}_{\text{BL}} {\text{+ C}}_{\text{SL}}\right) \times {\text{V}}_{\text{ReadWL}}$$

Here, V_{ReadWL} is the oscillation potential of the word line WL at the time of reading. As is apparent from the above equation, ΔV_{FB} decreases as the contribution ratio of C_{WL} decreases relative to the total capacitance C_{PL} + C_{WL} + C_{BL} + C_{SL} of the channel region 7. C_{BL} + C_{SL} is the capacitance of the PN junction. To increase the capacitance, for example, the diameter of the Si pillar 2 is increased. However, this is not desirable for miniaturization of the memory cell. In contrast, the length in the vertical direction of the first gate conductor layer 5a connected to the plate line PL may be further larger than the length in the vertical direction of the second gate conductor layer 5b connected to the word line WL, and thereby ΔV_{FB} can be further decreased without decreasing the degree of integration of the memory cells in plan view. The above-described conditions of the voltages applied to the bit line BL, the source line SL, the word line WL, and the plate line PL are examples for performing a read operation, and other operation conditions for performing a data read operation may be used.

A method for manufacturing a dynamic flash memory according to the present embodiment will be described with reference to FIG. 5AA to 5HC. FIGS. 5AA, 5BA, 5CA, 5DA, 5EA, 5FA, 5GA, and 5HA are plan views, FIGS. 5AB, 5BB, 5CB, 5DB, 5EB, 5FB, 5GB, and 5HB are sectional views taken along the line X-X′ of FIGS. 5AA, 5BA, 5CA, 5DA, 5EA, 5FA, 5GA, and 5HA, respectively, and FIGS. 5AC, 5BC, 5CC 5DC, 5EC, 5FC, 5GC, and 5HC are sectional views taken along the line Y-Y′ of FIGS. 5AA, 5BA, 5CA, 5DA, 5EA, 5FA, 5GA, and 5HA, respectively.

As illustrated in FIG. 5AA to 5AC, an N⁺ layer 11 (an example of “first impurity region” in the claims), a P layer 12 made of Si, and an N⁺ layer 13 are formed on a substrate 10 (an example of “substrate” in the claims) in this order from the bottom. In addition, mask material layers 14a, 14b, 14c, and 14d (an example of “first mask material layers” in the claims), which are circular in plan view, are formed. The substrate 10 may be a silicon on insulator (SOI) substrate, or may be a substrate formed of a single layer or a plurality of layers of Si or another semiconductor material. Alternatively, the substrate 10 may be a well layer formed of a single or a plurality of N layers or P layers.

Subsequently, as illustrated in FIG. 5BA to 5BC, the N⁺ layer 13, the P layer 12, and an upper portion of the N⁺ layer 11 are etched by using the mask material layers 14a to 14d as a mask, to form a Si pillar 12a (an example of “first semiconductor pillar” in the claims), a Si pillar 12b (an example of “second semiconductor pillar” in the claims), a Si pillar 12c (an example of “third semiconductor pillar” in the claims), a Si pillar 12d (not illustrated, an example of “fourth semiconductor pillar” in the claims), and N⁺ layers 13a, 13b, 13c, and 13d (each of which is an example of “second impurity region” in the claims, 13d is not illustrated) on an N⁺ layer 11a.

Subsequently, as illustrated in FIG. 5CA to 5CC, a HfO₂ layer 17 (an example of “first insulating layer” in the claims) functioning as a gate insulating layer is formed so as to cover the entire surface by using, for example, atomic layer deposition (ALD). Subsequently, a TiN layer (not illustrated) serving as a gate conductor layer is formed so as to cover the entire surface. Subsequently, the TiN layer is polished by chemical mechanical polishing (CMP) such that the upper surface position thereof corresponds to the upper surfaces of the mask material layers 14a to 14d. Subsequently, the TiN layer is etched by reactive ion etching (RIE) such that the upper surface position thereof in the vertical direction is near middle positions of the Si pillars 12a to 12d, to form a TiN layer 18 (an example of “first gate conductor layer” in the claims). The HfO₂ layer 17 may be another insulating layer formed of a single layer or a plurality of layers as long as it functions as a gate insulating layer. The TiN layer 18 may be another conductor layer formed of a single layer or a plurality of layers as long as it functions as a gate conductor layer. It is desired that the TiN layer be etched such that the upper surface position thereof in the vertical direction is above the middle positions of the Si pillars 12a to 12d.

Subsequently, as illustrated in FIG. 5DA to 5DC, a SiO₂ layer 23 (an example of “first insulating layer” in the claims) is formed on the TiN layer 18.

Subsequently, as illustrated in FIG. 5EA to 5EC, a portion of the HfO₂ layer 17 above the SiO₂ layer 23 is etched to form HfO₂ layers 17a (an example of “first gate insulating layers” in the claims). Subsequently, HfO₂ layers 17b (an example of “second gate insulating layers” in the claims) are formed over the entire surface. Subsequently, a TiN layer (not illustrated) is formed to cover the entire surface by using chemical vapor deposition (CVD). Subsequently, the TiN layer is subjected to CMP and is etched by using a RIE method such that the upper surface position thereof is near the lower ends of the N⁺ layers 13a to 13d. Subsequently, a SiN layer 27a (an example of “second mask material layer” in the claims) that surrounds the side surfaces of the N⁺ layers 13a and 13b and the mask material layers 14a and 14b and that is continuous therebetween is formed. Similarly, a SiN layer 27b (an example of “third mask material layer” in the claims) that surrounds the side surfaces of the N⁺ layers 13c and 13d and the mask material layers 14c and 14d and that is continuous therebetween is formed. Subsequently, the TiN layer is etched by using the SiN layers 27a and 27b as a mask, to form a TiN layer 26a (an example of “second gate conductor layer” in the claims) and a TiN layer 26b (an example of a “third gate conductor layer” in the claims). Here, a length L1 between intersection points of the outer periphery lines of the HfO₂ layers 17b surrounding the Si pillars 12a and 12b and the line X-X′ is smaller than twice a width L2 of the SiN layers 27a and 27b on the line Y-Y′, and a length L3 between intersection points of the outer periphery lines of the HfO₂ layers 17b surrounding the Si pillars 12a and 12c and the line Y-Y′ is larger than twice the width L2, and thus the SiN layer 27a can be formed so as to be continuous between the Si pillars 12a and 12b and separated between the Si pillars 12a and 12c. Similarly, the SiN layer 27b is formed so as to be continuous between the Si pillars 12c and 12d and separated between the Si pillars 12a and 12c.

Subsequently, as illustrated in FIG. 5FA to 5FD, a SiO₂ layer 29 including holes 31aa, 31ab, 31ac, 31ba, 31bb, 31bc, 31ca, 31cb, and 31cc (an example of “first hole” in the claims) is formed between and around the side surfaces of the TiN layers 26a and 26b and the SiN layers 27a and 27b. The holes 31aa, 31ab, 31ac, 31ba, 31bb, 31bc, 31ca, 31cb, and 31cc are formed such that the upper end positions thereof are below the upper end positions of the TiN layers 26a and 26b indicated by the dotted line in FIG. 5FD.

Subsequently, as illustrated in FIG. 5GA to 5GD, the mask material layers 14a to 14d are etched to form contact holes 30a, 30b, 30c, and 30d (an example of “first contact holes” in the claims).

Subsequently, as illustrated in FIG. 5HA to 5HC, a bit line BL1 conductor layer 32a (an example of “first wiring conductor layer” in the claims) connected to the N⁺ layers 13a and 13c through the contact holes 30a and 30c is formed, and a bit line BL2 conductor layer 32b (an example of “second wiring conductor layer” in the claims) connected to the N⁺ layers 13b and 13d through the contact holes 30b and 30d is formed. Subsequently, a SiO₂ layer 33 including holes 34a, 34b, and 34c (an example of “second hole” in the claims) is formed between and on both sides of the bit line BL1 conductor layer 32a and the bit line BL2 conductor layer 32b. Accordingly, a dynamic flash memory is formed on the substrate 10. The TiN layers 26a and 26b serve as word line conductor layers WL1 and WL2, the TiN layer 18 serves as a plate line conductor layer PL also serving as a gate conductor layer, and the N⁺ layer 11a serves as a source line conductor layer SL also serving as a source impurity layer.

FIG. 5I illustrates a schematic structural diagram of the dynamic flash memory illustrated in FIG. 5HA to 5HC. The N⁺ layer 11a of the source line conductor layer SL is formed so as to be continuous over the entire surface. The plate line conductor layer PL is also formed so as to be continuous over the entire surface. The TiN layer 26a connected to the word line conductor layer WL1 is formed so as to be continuous between the adjacent Si pillars 12a and 12b in the X direction. Likewise, the TiN layer 26b connected to the word line conductor layer WL2 is formed so as to be continuous between the adjacent Si pillars 12c and 12d in the X direction. The bit line conductor layer BL1 connected to the N⁺ layers 13a and 13c and the bit line conductor layer BL2 connected to the N⁺ layers 13b and 13d are formed in the Y direction orthogonal to the X direction.

In FIG. 1, the length in the vertical direction of the first gate conductor layer 5a connected to the plate line PL is larger than the length in the vertical direction of the second gate conductor layer 5b connected to the word line WL, so that C_{PL} > C_{WL} holds. However, only adding of the plate line PL decreases a coupling ratio (C_{WL}/ (C_{PL} + C_{WL} + C_{BL} + C_{SL})) of the capacitive coupling of the word line WL to the channel region 7. As a result, the potential variation ΔV_{FB} of the channel region 7 of the floating body reduces.

A voltage V_{ErasePL} to be applied to the plate line PL may be a fixed voltage regardless of an operation mode. The voltage V_{ErasePL} to be applied to the plate line PL at the time of erasing may be, for example, 0 V. The voltage V_{ErasePL} to be applied to the plate line PL may be a fixed voltage or a voltage which changes with time as long as the voltage satisfies a condition in which a dynamic flash memory operation can be performed.

In FIG. 1, the Si pillar 2 may have a sectional shape that is circular, elliptical, or rectangular, so as to perform the dynamic flash memory operation described in the present embodiment. Circular, elliptical, and rectangular dynamic flash memory cells may be disposed together on the same chip.

In FIG. 1, the potential distributions of the first channel region 7a and the second channel region 7b are connected to each other in the portion of the channel region 7 surrounded by the insulating layer 6 in the vertical direction. Accordingly, the first channel region 7a and the second channel region 7b of the channel region 7 are connected to each other in the region surrounded by the insulating layer 6 in the vertical direction.

In FIG. 5FA to 5FD, the holes 31aa, 31ab, 31ac, 31ba, 31bb, 31bc, 31ca, 31cb, and 31cc are formed so as to be isolated from each other. Alternatively, the distance between the Si pillars 12a and 12c and the distance between the Si pillars 12b and 12d may be increased so as to connect the holes 31aa, 31ab, and 31ac, connect the holes 31ba, 31bb, and 31bc, and connect the holes 31ca, 31cb, and 31cc.

In FIG. 5EA to 5EC, after the TiN layers 26a and 26b are formed, a HfO₂ layer surrounding the Si pillars 12a to 12d and serving as a gate insulating layer, and a TiN layer serving as a fourth gate conductor layer isolated from the TiN layers 26a and 26b by an insulating layer may be formed between the TiN layers 26a and 26b and the lower ends of the N⁺ layers 13a to 13d in the vertical direction. In this case, the TiN layer serving as the fourth gate conductor layer and the TiN layer 18 have the same shape as the TiN layers 26a and 26b in plan view. The individual TiN layers are connected to the word line or the plate line.

The present embodiment provides the following features.

### Feature 1

In the dynamic flash memory cell of the present embodiment, the N⁺ layers 3a and 3b serving as the source and drain, the channel region 7, the first gate insulating layer 4a, the second gate insulating layer 4b, the first gate conductor layer 5a, and the second gate conductor layer 5b are formed in a pillar shape as a whole. The N⁺ layer 3a serving as the source is connected to the source line SL, the N⁺ layer 3b serving as the drain is connected to the bit line BL, the first gate conductor layer 5a is connected to the plate line PL, and the second gate conductor layer 5b is connected to the word line WL. In this structure, the gate capacitance of the first gate conductor layer 5a connected to the plate line PL is larger than the gate capacitance of the second gate conductor layer 5b connected to the word line WL. In this dynamic flash memory cell, the first gate conductor layer 5a and the second gate conductor layer 5b are stacked in the vertical direction. Thus, even in the structure in which the gate capacitance of the first gate conductor layer 5a connected to the plate line PL is larger than the gate capacitance of the second gate conductor layer 5b connected to the word line WL, the memory cell area is not large in plan view. Accordingly, higher performance and higher integration of the dynamic flash memory cells can be simultaneously realized.

### Feature 2

The first gate conductor layer 5a connected to the plate line PL of the dynamic flash memory cell according to the first embodiment of the present invention has the following five roles (1) to (5).
(1) When the dynamic flash memory cell performs a write operation or a read operation, the voltage of the word line WL oscillates up and down. At this time, the plate line PL functions to reduce the capacitive coupling ratio between the word line WL and the channel region 7. As a result, when the voltage of the word line WL oscillates up and down, an influence of the voltage change in the channel region 7 can be significantly reduced. This makes it possible to increase the difference in the threshold voltage of the SGT of the word line WL indicating the logic “0” and “1”. This leads to an increase in the operation margin of the dynamic flash memory cell.
(2) When the dynamic flash memory cell performs an erase operation, a write operation, or a read operation, both the first gate conductor layer 5a connected to the plate line PL and the second gate conductor layer 5b connected to the word line WL function as the gate of the SGT. When a current flows from the bit line BL to the source line SL, a short channel effect of the SGT can be reduced. In this way, the short channel effect is reduced by the first gate conductor layer 5a connected to the plate line PL. Accordingly, a data hold characteristic can be improved.
(3) Upon a write operation of the dynamic flash memory cell being started, a positive hole group is gradually accumulated in the channel region 7, and the threshold voltages of a first MOS transistor having the plate line PL and a second MOS transistor having the word line WL decrease. At this time, the decrease in the threshold voltage of the first MOS transistor having the plate line PL promotes an impact ionization phenomenon at the time of the write operation. As a result, the plate line PL exerts positive feedback at the time of writing, and the speed of the write operation increases.
(4) In the dynamic flash memory cell that has performed “1” writing, the threshold voltage of the first MOS transistor having the plate line PL decreases. As a result, when a positive bias is applied to the plate line PL, an inversion layer is constantly formed on the inner side from the first gate conductor layer 5a connected to the plate line PL. As a result, a layer of electrons accumulated in the inversion layer formed on the inner side from the first gate conductor layer 5a connected to the plate line PL serves as a conductor radio wave shield layer. Accordingly, the dynamic flash memory cell that has performed “1” writing is shielded from disturbance noise from the surroundings.
(5) At the time of a write operation of the dynamic flash memory cell, photons are generated by an impact ionization phenomenon. The generated photons are repeatedly reflected by the first gate conductor layer 5a and the second gate conductor layer 5b, and travel in the vertical direction in the Si pillar 2. At this time, the plate line PL has a light shield effect with respect to photons so that the photons generated at the time of writing do not destroy data in an adjacent memory cell in the horizontal direction.

### Feature 3

As illustrated in FIG. 5I, the TiN layer 18 connected to the plate line PL is formed so as to be continuous between the Si pillars 12a to 12d in the X and Y directions. This indicates that there is no pattern formed by lithography in the memory cell region. Accordingly, the cost of the mask to be used can be reduced, and the process can be simplified.

### Feature 4

As illustrated in FIG. 5EA to 5EC, the length L1 between the intersection points of the outer periphery lines of the HfO₂ layers 17b surrounding the Si pillars 12a and 12b and the line X-X′ is smaller than twice the width L2 of the SiN layers 27a and 27b on the line Y-Y′, and the length L3 between the intersection points of the outer periphery lines of the HfO₂ layers 17b surrounding the Si pillars 12a and 12c and the line Y-Y′ is larger than twice the width L2, and thus the SiN layer 27a can be formed so as to be continuous between the Si pillars 12a and 12b and separated between the Si pillars 12b and 12c. Similarly, the SiN layer 27b is formed so as to be continuous between the Si pillars 12c and 12d and separated between the Si pillars 12a and 12c. The SiN layers 27a and 27b are formed in a self-aligned manner with respect to the Si pillars 12a to 12d. Thus, the TiN layers 26a and 26b, which are word lines WL formed by using the SiN layers 27a and 27b as an etching mask and are gate conductor layers, are formed in a self-aligned manner with respect to the Si pillars 12a to 12d. Because the TiN layers 26a and 26b are formed in a self-aligned manner, the dynamic flash memory can be highly integrated. The TiN layers 26a and 26b are formed without using a mask pattern in the lithography process, and thus the cost of the mask to be used can be reduced, and the process can be simplified.

### Feature 5

As illustrated in FIG. 5GA to 5GD, the contact holes 30a to 30d are formed by removing the mask material layers 14a to 14d used to form the Si pillars 12a to 12d. As illustrated in FIG. 5HA to 5HC, the N⁺ layers 13a and 13c are connected to the bit line BL1 conductor layer 32a through the contact holes 30a and 30c, and also the N⁺ layers 13b and 13d are connected to the bit line BL2 conductor layer 32b through the contact holes 30b and 30d. The contact holes 30a to 30d are formed for the Si pillars 12a to 12d in a self-aligned manner. A lithography process is not required to form the contact holes 30a to 30d. Accordingly, a low-cost and high-density dynamic flash memory can be formed.

### Second Embodiment

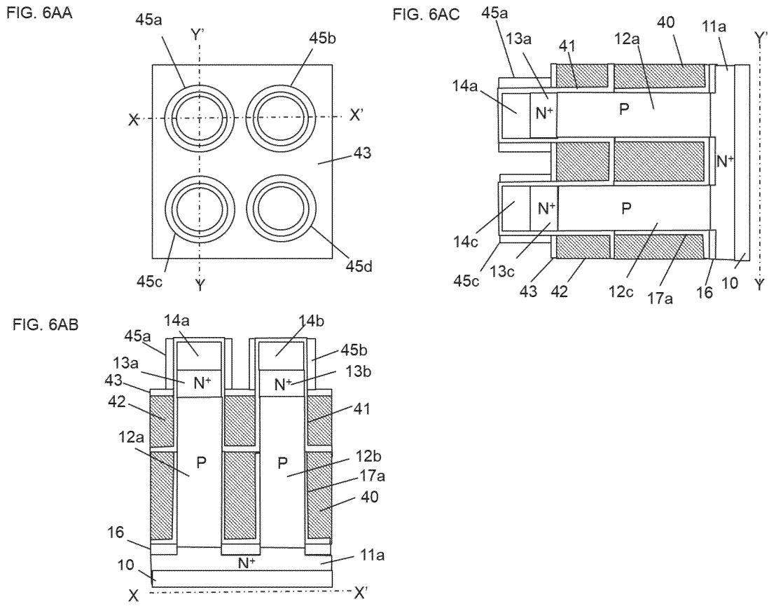

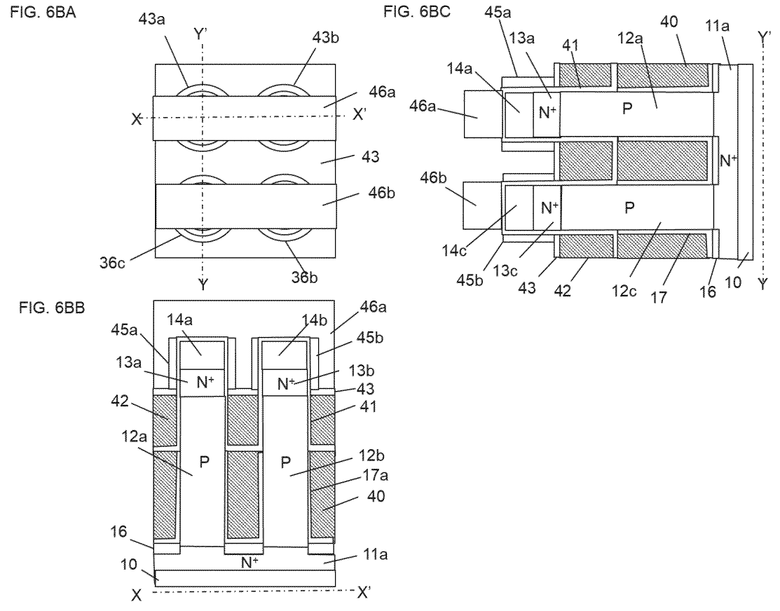

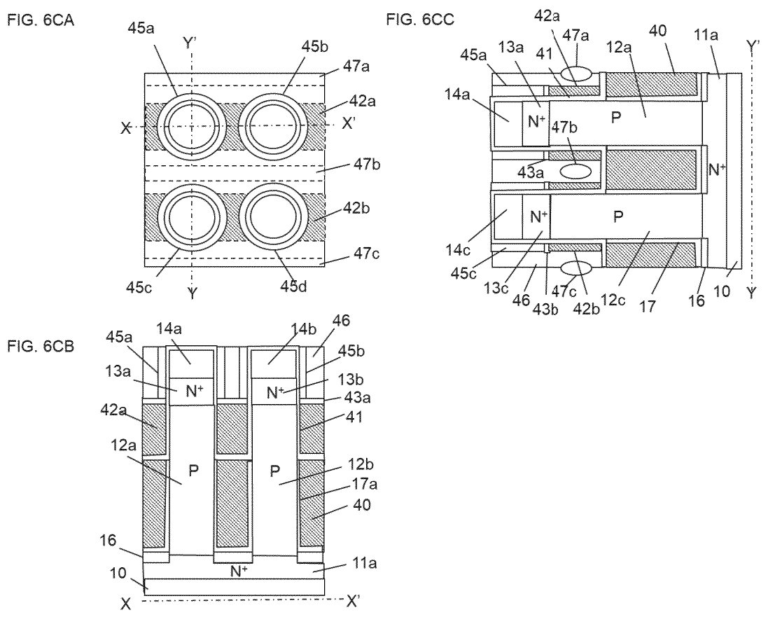

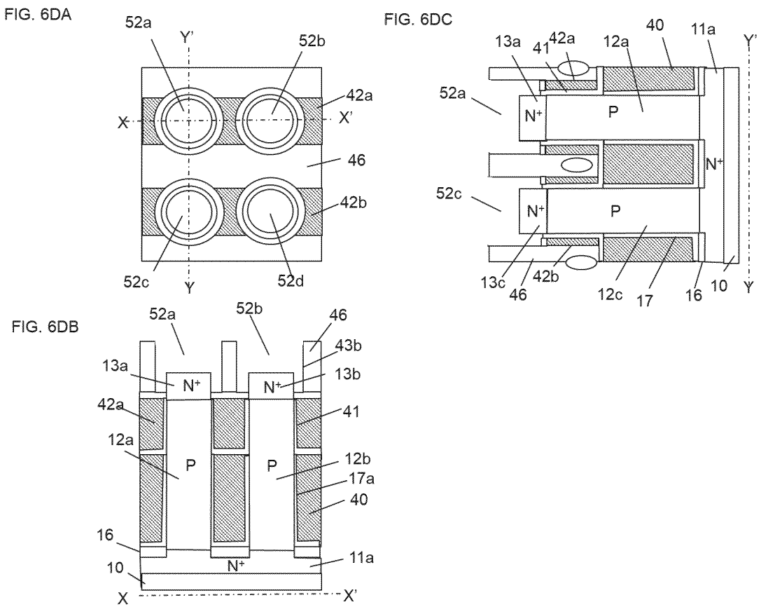

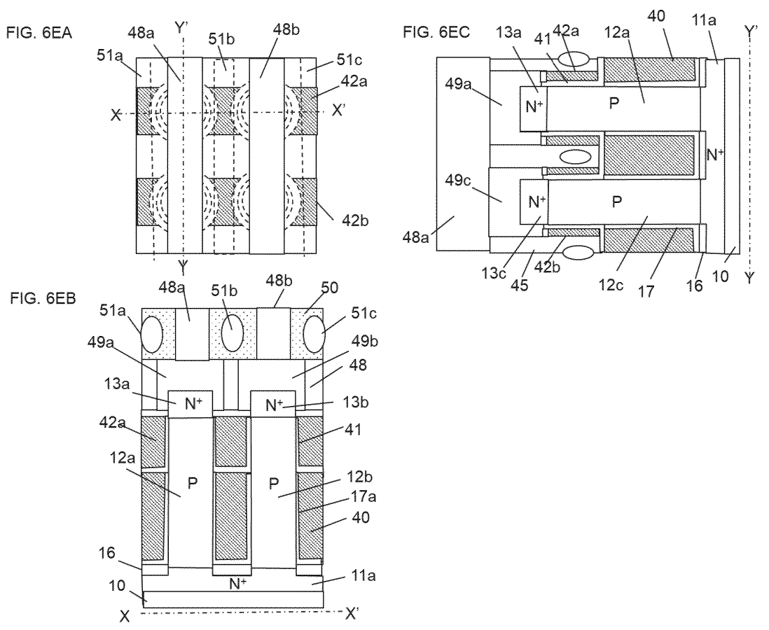

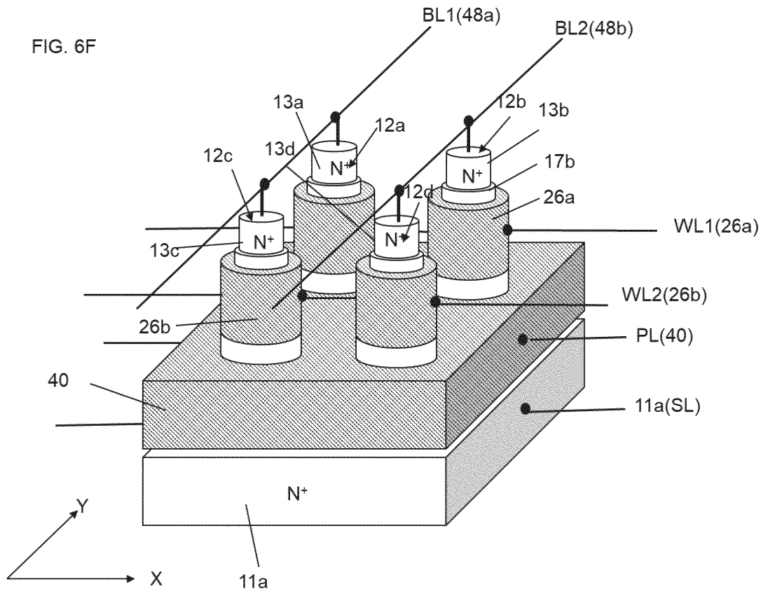

A method for manufacturing a dynamic flash memory according to a second embodiment will be described with reference to FIG. 6AA to 6EC. FIGS. 6AA, 6BA, 6CA, 6DA, and 6EA are plan views, FIGS. 6AB, 6BB, 6CB, 6DB, and 6EB are sectional views taken along the line X-X′ of FIGS. 6AA, 6BA, 6CA, 6DA, and 6EA, respectively, and FIGS. 6AC, 6BC, 6CC, 6DC, and 6EC are sectional views taken along the line Y-Y′ of FIGS. 6AA, 6BA, 6CA, 6DA, and 6EA, respectively.

The steps illustrated in FIG. 5AA to 5CC are performed. Subsequently, as illustrated in FIG. 6AA to 6AC, a portion of the HfO₂ layer 17 above the upper surface of a TiN layer 40 (corresponding to the TiN layer 18 in FIG. 5DA to 5DC) in the vertical direction is removed to form the HfO₂ layers 17a. Subsequently, a HfO₂ layer 41 is formed over the entire structure. Subsequently, a TiN layer (not illustrated) is formed to cover the entire structure. Subsequently, the TiN layer is polished by a CMP method such that the upper surface thereof corresponds to the upper surfaces of the mask material layers 14a to 14d. Subsequently, the TiN layer is etched by using a RIE method such that the upper surface position thereof is near the lower ends of the N⁺ layers 13a to 13d, to form a TiN layer 42. Subsequently, an aluminum oxide (AlO) layer 43 is formed, on the TiN layer 42, around the N⁺ layers 13a to 13d. Subsequently, a SiN layer (not illustrated) is formed to cover the entire structure. Subsequently, the SiN layer is polished by a CMP method such that the upper surface position thereof corresponds to the upper surfaces of the mask material layers 14a to 14d. Subsequently, the SiN layer is etched by a RIE method to form SiN layers 45a, 45b, 45c, and 45d (an example of “fourth mask material layers” in the claims) so as to surround the HfO₂ layer 41 on the side surfaces of the N⁺ layers 13a to 13d and the mask material layers 14a to 14d.

Subsequently, as illustrated in FIG. 6BA to 6BC, a mask material layer 46a (an example of “fifth mask material layer” in the claims) overlapping the Si pillars 12a and 12b and extending in the direction of the line X-X′ in plan view, and a mask material layer 46b (an example of “sixth mask material layer” in the claims) overlapping the Si pillars 12c and 12d and extending in the direction of the line X-X′ in plan view are formed. The mask material layers 46a and 46b may be formed on the mask material layers 14a to 14d and a SiO₂ layer that surrounds the side surfaces of the SiN layers 45a and 45b.

Subsequently, as illustrated in FIG. 6CA to 6CC, the AlO layer 43 and the TiN layer 42 are etched by a RIE method by using the mask material layers 14a to 14d (an example of “seventh mask material layers” in the claims), the SiN layers 45a to 45d, and the mask material layers 46a and 46b as a mask, to form AlO layers 43a and 43b and TiN layers 42a and 42b. Subsequently, a SiO₂ layer (not illustrated) is formed to cover the entire surface and polished by a CMP method such that the upper surface position thereof corresponds to the upper surfaces of the mask material layers 14a to 14d, to form a SiO₂ layer 46 (an example of “second insulating layer” in the claims). The SiO₂ layer 46 is formed so as to include holes 47a, 47b, and 47c extending in the direction of the line X-X′ in plan view, between and on both sides of the TiN layers 42a and 42b. The holes 47a to 47c are formed such that the upper surface positions thereof are below the upper end positions of the TiN layers 42a and 42b.

Subsequently, as illustrated in FIG. 6DA to 6DC, the mask material layers 14a to 14d, the SiN layers 45a to 45d, and the HfO₂ layer 41 surrounding the mask material layers 14a to 14d and the N⁺ layers 13a to 13d are etched to form contact holes 52a, 52b, 52c, and 52d (an example of “second contact holes” in the claims).

Subsequently, as illustrated in FIG. 6EA to 6EC, conductor layers 49a, 49b, 49c, and 49d are formed in the contact holes 52a to 52d. Subsequently, a bit line BL1 conductor layer 48a that is in contact with the conductor layers 49a and 49c and extends in the direction of the line Y-Y′ in plan view, and a bit line BL2 conductor layer 48b that is in contact with the conductor layers 49b and 49d and extends in the direction of the line Y-Y′ in plan view are formed. Subsequently, a SiO₂ layer 50 including holes 51a, 51b, and 51c and extending in the direction of the line Y-Y′ is formed between and on both sides of the bit line BL1 conductor layer 48a and the bit line BL2 conductor layer 48b. Accordingly, a dynamic flash memory is formed on the substrate 10 as in the first embodiment.

FIG. 6F illustrates a schematic structural diagram of the dynamic flash memory illustrated in FIG. 6EA to 6EC. The N⁺ layer 11a of the source line conductor layer SL is formed so as to be continuous over the entire surface. The TiN layer 40 connected to the plate line PL is also formed so as to be continuous over the entire surface. The TiN layer 26a connected to the word line WL1 is formed so as to be continuous between the adjacent Si pillars 12a and 12b in the X direction. Likewise, the TiN layer 26b connected to the word line WL2 is formed so as to be continuous between the adjacent Si pillars 12c and 12d in the X direction. The bit line BL1 connected to the N⁺ layers 13a and 13c and the bit line BL2 connected to the N⁺ layers 13b and 13d are formed in the Y direction orthogonal to the X direction.

In FIG. 6DA to 6DC, the contact holes 52a, 52b, 52c, and 52d are formed by etching the mask material layers 14a to 14d, the SiN layers 45a to 45d, and the HfO₂ layer 41 surrounding the mask material layers 14a to 14d and the N⁺ layers 13a to 13d. Alternatively, the contact holes may be formed by removing the mask material layers 14a to 14d and the HfO₂ layer 41 without removing the SiN layers 45a to 45d. The contact holes in this case are formed similarly to the contact holes 30a to 30d in FIG. 5GA to 5GD.

Before forming of the HfO₂ layer 41, the exposed side surfaces of the Si pillars 12a to 12d may be oxidized at a low temperature or room temperature to form a thin SiO₂ layer. In this case, the thin SiO₂ layer and the HfO₂ layer 41 serve as a gate insulating layer. The thin SiO₂ layer may be formed by an atomic layer deposition (ALD) method. In this case, the thin SiO₂ layer is also formed on the TiN layer 40.

In FIG. 6DA to 6DC, the contact holes 52a, 52b, 52c, and 52d are formed by etching the mask material layers 14a to 14d, the SiN layers 45a to 45d, and the HfO₂ layer 41 surrounding the mask material layers 14a to 14d and the N⁺ layers 13a to 13d. Alternatively, the mask material layers 14a to 14d may be etched, and contact holes may be formed on the N⁺ layers 13a to 13d in the same manner as the manner in which the contact holes 30a to 30d illustrated in FIG. 5GA to 5GD are formed.

The present embodiment provides the following features.

### Feature 1

Also in the present embodiment, as in the first embodiment, the gate TiN layer 40 connected to the plate line PL is formed so as to be continuous between the Si pillars 12a to 12d in the X and Y directions. This indicates that there is no pattern formed by lithography in the memory cell region. Accordingly, the cost of the mask to be used can be reduced, and the process can be simplified.

### Feature 2

In the first embodiment, as illustrated in FIG. 5EA to 5EC, the SiN layer 27a serving as a mask material layer is formed so as to be continuous between the Si pillars 12a and 12b, and the SiN layer 27b is formed so as to be continuous between the Si pillars 12c and 12d. To form the SiN layers 27a and 27b, it is necessary that the Si pillars 12a and 12b be close to each other and that the Si pillars 12c and 12d be close to each other. In contrast, in the present embodiment, the mask material layer 46a overlapping the Si pillars 12a and 12b and the SiN layers 45a and 45b and extending in the direction of the line X-X′ in plan view, and the mask material layer 46b overlapping the Si pillars 12c and 12d and the SiN layers 45c and 45d and extending in the direction of the line X-X′ in plan view are formed. In addition, the TiN layer 42 is etched by using the SiN layers 45a to 45d and the mask material layers 46a and 46b as a mask, to form the TiN layers 42a and 42b serving as word line conductor layers. In this way, the SiN layers 45a to 45d need not be formed so as to be continuous between the Si pillars 12a and 12b and between the Si pillars 12c and 12d. This facilitates the process of forming the SiN layers 45a to 45d. In addition, it becomes easy to increase the size of the holes 47a to 47c and 51a to 51c and to optimize the arrangement thereof.

### Other Embodiments

Although the Si pillars 2 and 12a to 12d are formed in the present invention, semiconductor pillars made of another semiconductor material may be used. The same applies to other embodiments according to the present invention.

The N⁺ layers 3a, 3b, 11, and 13 in the first embodiment may be formed of layers made of Si containing donor impurities or another semiconductor material. Alternatively, the N⁺ layers 3a, 3b, 11, and 13 may be formed of layers made of different semiconductor materials. The N⁺ layers may be formed by an epitaxial crystal growth method or another method. The same applies to other embodiments according to the present invention.

In the first embodiment, a low-resistance conductor layer made of tungsten (W) or the like may be formed in the N⁺ layer 11a in the outer periphery portion of the Si pillars 12a to 12d. Alternatively, for example, the N⁺ layer 11a for the Si pillars 12a and 12b and the N⁺ layer 11a for the Si pillars 12c and 12d may be isolated from each other by shallow trench isolation (STI). The same applies to other embodiments according to the present invention.

The mask material layers 14a to 14d illustrated in FIG. 5AA to 5AC may be layers made of another material including an organic or inorganic material and formed of a single layer or a plurality of layers as long as the material meets the purpose of the present invention, for example, a SiO₂ layer, an aluminum oxide (Al₂O₃, also referred to as AlO) layer, or a SiN layer. The same applies to other embodiments according to the present invention.

The thicknesses and shapes of the mask material layers 14a to 14d illustrated in FIG. 5AA to 5AC are changed by polishing by CMP, RIE etching, and washing performed later. The change has no problem as long as the change meets the purpose of the present invention. The same applies to other embodiments according to the present invention.

In FIG. 5EA to 5EC, the upper end positions of the SiN layers 27a and 27b correspond to the upper end positions of the mask material layers 14a to 14d. Alternatively, in the RIE step, the upper ends of the SiN layers 27a and 27b in the vertical direction may be located on the side surfaces of the mask material layers 14a to 14d as long as the condition of covering the side surfaces of the N⁺ layers 13a to 13d is satisfied. The same applies to other embodiments according to the present invention.

In the first embodiment, the plate line PL and the TiN layer 18 serving as the gate conductor layer 5a connected to the plate line PL are used. Alternatively, instead of the TiN layer 18, a single conductive material layer or a combination of a plurality of conductive material layers may be used. Similarly, the word line WL and the TiN layers 26a and 26b serving as the gate conductor layer 5b connected to the word line WL are used. Alternatively, instead of the TiN layers 26a and 26b, a single conductive material layer or a combination of a plurality of conductive material layers may be used. In addition, the gate TiN layer may be, on its outer side, connected to a wiring metal layer such as a W layer. The same applies to other embodiments according to the present invention.

The conductor layers 49a, 49b, 49c, and 49d illustrated in FIG. 6EA to 6EC may be formed of a single or a plurality of metal layers, or may be formed by forming an N⁺ layer in contact with the N⁺ layers 13a to 13d by, for example, a selective epitaxial crystal growth method, and covering the N+ layer with a metal layer. The same applies to other embodiments according to the present invention.

The SiN layers 27a and 27b illustrated in FIG. 5EA to 5EC are etching mask layers for forming the TiN layers 26a and 26b. The SiN layers 27a and 27b may each be another material layer composed of a single or a plurality of layers as long as the function of the etching mask in the present embodiment is obtained. The same applies to other embodiments according to the present invention.

In the second embodiment, the HfO₂ layers 17a and 41 serving as gate insulating layers are formed so as to surround the Si pillars 12a to 12d, but each may be another material layer formed of a single or a plurality of layers. The same applies to other embodiments according to the present invention.

In FIG. 6AA to 6AC, the aluminum oxide (AlO) layer 43 is formed, on the TiN layer 42, around the N⁺ layers 13a to 13d. The AlO layer 43 may be another material layer formed of a single or a plurality of layers as long as an effect required in this step is obtained. The same applies to other embodiments according to the present invention.

In the description referring to FIG. 5HA to 5HC, the bit line BL1 conductor layer 32a and the bit line BL2 conductor layer 32b are formed in one step. Alternatively, the inside of the contact holes 30a to 30d may be formed by a first conductor layer, and then conductor layers serving as the bit line BL1 conductor layer and the bit line BL2 conductor layer may be formed so as to be connected to the first conductor layer. In FIG. 6EA to 6EC, the SiO₂ layer 50 is formed after the bit line BL1 conductor layer 48a and the bit line BL2 conductor layer 48b are formed. Alternatively, after the SiO₂ layer 50 is formed, contact holes may be formed on the N⁺ layers 13a to 13d, and then the bit line BL1 conductor layer 48a and the bit line BL2 conductor layer 48b may be formed.

In the first embodiment, the Si pillars 12a to 12d have a circular shape in plan view. The Si pillars 12a to 12d may have a circular shape, an elliptical shape, a shape elongated in one direction, or the like in plan view. Also in a logic circuit region formed apart from the dynamic flash memory cell region, Si pillars having different shapes in plan view may be formed together in the logic circuit region in accordance with logic circuit design. The same applies to other embodiments according to the present invention.

In FIG. 1, the positional relationship between the first gate conductor layer 5a and the second gate conductor layer 5b may be reversed in the vertical direction. In FIG. 5EA to 5EC, the positional relationship between the TiN layer 18 and the TiN layers 26a and 26b may be reversed in the vertical direction. Also in this case, a normal dynamic flash memory operation can be performed. The same applies to other embodiments according to the present invention.

In the first embodiment and the second embodiment, the source line SL is negatively biased to discharge the positive hole group in the channel region 7 serving as the floating body FB during an erase operation. Alternatively, the bit line BL may be negatively biased, or the source line SL and the bit line BL may be negatively biased, instead of the source line SL, to perform an erase operation. Alternatively, an erase operation may be performed under another voltage condition. The same applies to other embodiments according to the present invention.

In FIG. 1, either or both of the first gate conductor layer 5a and the second gate conductor layer 5b may be divided in plan view or in the vertical direction. The same applies to other embodiments according to the present invention.

In the present invention, various embodiments and modifications can be made without departing from the broad spirit and scope of the present invention. The above-described embodiments are for explaining an example of the present invention, and do not limit the scope of the present invention. The above-described embodiments and modifications can be combined as appropriate. Furthermore, the above-described embodiments from which one or some of the constituent elements are removed as appropriate are also within the scope of the technical idea of the present invention.

According to a method for manufacturing a memory device including a pillar-shaped semiconductor element of the present invention, a high-density and high-performance dynamic flash memory can be obtained.

What is claimed is:

1. A method for manufacturing a memory device including a pillar-shaped semiconductor element,
the memory device being configured to control voltages to be applied to a first gate conductor layer, a second gate conductor layer, a third gate conductor layer, a first impurity region, and second impurity regions to perform a data write operation, a data read operation, and a data erase operation,
the method comprising the steps of:
forming a first semiconductor pillar, a second semiconductor pillar, a third semiconductor pillar, and a fourth semiconductor pillar that stand on a substrate in a vertical direction, the first semiconductor pillar and the second semiconductor pillar having respective midpoints on a first line in plan view and being disposed adjacent to each other, the third semiconductor pillar and the fourth semiconductor pillar having respective midpoints on a second line parallel to the first line in plan view and being disposed adjacent to each other;
forming first gate insulating layers and the first gate conductor layer, the first gate insulating layers each surrounding a corresponding one of the first to fourth semiconductor pillars, the first gate conductor layer surrounding the first gate insulating layers;
forming second gate insulating layers adjacent to the first gate insulating layers in the vertical direction and each surrounding a side surface of a corresponding one of the first to fourth semiconductor pillars;
forming the second gate conductor layer and the third gate conductor layer that surround the respective second gate insulating layers, the second gate conductor layer being continuous between the first semiconductor pillar and the second semiconductor pillar on the first line and being isolated from the first gate conductor layer in the vertical direction, the third gate conductor layer being continuous between the third semiconductor pillar and the fourth semiconductor pillar on the second line and being isolated from the first gate conductor layer in the vertical direction;
before or after the forming of the first to fourth semiconductor pillars, forming the first impurity region connected to bottom portions of the first to fourth semiconductor pillars;
before or after the forming of the first to fourth semiconductor pillars, forming the second impurity regions each disposed at a top portion of a corresponding one of the first to fourth semiconductor pillars; and
forming a first wiring conductor layer and a second wiring conductor layer, the first wiring conductor layer being connected to the second impurity regions at the top portions of the first semiconductor pillar and the third semiconductor pillar, the second wiring conductor layer being connected to the second impurity regions at the top portions of the second semiconductor pillar and the fourth semiconductor pillar.

2. The method for manufacturing a memory device including a pillar-shaped semiconductor element according to claim 1, wherein
a first length is smaller than a second length in plan view, the first length being a length between two opposed points among intersection points between the first line and two outer periphery lines of the first gate insulating layers surrounding the first semiconductor pillar and the second semiconductor pillar, the second length being a length between two opposed points among intersection points between a third line passing through the midpoint of the first semiconductor pillar and orthogonal to the first line and two outer periphery lines of the second gate insulating layers surrounding the first semiconductor pillar and the third semiconductor pillar,
the second length is larger than twice a third length in plan view, the third length being a thickness of the first gate conductor layer located on the third line and surrounding the first semiconductor pillar, and
the first length is smaller than twice the third length in plan view.

3. The method for manufacturing a memory device including a pillar-shaped semiconductor element according to claim 1, further comprising the steps of:
after the forming of the second gate insulating layers, forming a first conductor layer on outer periphery portions of the second gate insulating layers, the first conductor layer having an upper surface position located near lower ends of the second impurity regions in the vertical direction;
forming first mask material layers, a second mask material layer, and a third mask material layer, the first mask material layers each being disposed on the top portion of a corresponding one of the first to fourth semiconductor pillars, the second mask material layer being continuous between the first semiconductor pillar and the second semiconductor pillar, the third mask material layer being continuous between the third semiconductor pillar and the fourth semiconductor pillar, the second mask material layer and the third mask material layer being disposed on the first conductor layer, surrounding side surfaces of the second impurity regions, and being separated from each other; and
etching the first conductor layer by using the first mask material layers, the second mask material layer, and the third mask material layer as a mask, to form the second gate conductor layer and the third gate conductor layer.

4. The method for manufacturing a memory device including a pillar-shaped semiconductor element according to claim 3, further comprising the steps of:
after the forming of the second gate insulating layers, forming a second conductor layer on outer periphery portions of the second gate insulating layers, the second conductor layer having an upper surface position corresponding to an upper end of the second gate conductor layer in the vertical direction;
forming a first insulating layer on the second conductor layer;
forming fourth mask material layers disposed on the first insulating layer, surrounding the respective first mask material layers and the respective second impurity regions, and separated from each other;
forming a fifth mask material layer and a sixth mask material layer that are disposed on the fourth mask material layers, the fifth mask material layer at least partially overlapping the first semiconductor pillar and the second semiconductor pillar in plan view, the sixth mask material layer at least partially overlapping the third semiconductor pillar and the fourth semiconductor pillar in plan view; and
etching the second conductor layer by using seventh mask material layers each disposed on the top portion of a corresponding one of the first to fourth semiconductor pillars, the fifth mask material layer, and the sixth mask material layer as a mask, to form the second gate conductor layer and the third gate conductor layer.

5. The method for manufacturing a memory device including a pillar-shaped semiconductor element according to claim 1, wherein
the memory device is formed such that a wiring line connected to the first impurity region is a source line, a wiring line connected to the second impurity regions is a bit line, one of a wiring line connected to the first gate conductor layer and a wiring line connected to the second gate conductor layer and the third gate conductor layer is a word line, and an other of the wiring line connected to the first gate conductor layer and the wiring line connected to the second gate conductor layer and the third gate conductor layer is a first drive control line, and
the memory device is configured to perform the data write operation, the data read operation, and the data erase operation by applying voltages to the source line, the bit line, the first drive control line, and the word line.

6. The method for manufacturing a memory device including a pillar-shaped semiconductor element according to claim 1, wherein
the memory device is formed such that a first gate capacitance between the first gate conductor layer and the first semiconductor pillar is larger than a second gate capacitance between the second gate conductor layer and the first semiconductor pillar.

7. The method for manufacturing a memory device including a pillar-shaped semiconductor element according to claim 1, wherein
a first hole is formed between the second gate conductor layer and the third gate conductor layer in plan view.

8. The method for manufacturing a memory device including a pillar-shaped semiconductor element according to claim 1, wherein
a second hole is formed between the first wiring conductor layer and the second wiring conductor layer.

9. The method for manufacturing a memory device including a pillar-shaped semiconductor element according to claim 3, further comprising the steps of:
etching the first conductor layer by using the first mask material layers, the second mask material layer, and the third mask material layer as a mask, to form the second gate conductor layer and the third gate conductor layer;
forming a second insulating layer surrounding side surfaces of the second gate conductor layer, the third gate conductor layer, the second mask material layer, and the third mask material layer;
etching the first mask material layers on the top portions of the first to fourth semiconductor pillars by using the second mask material layer, the third mask material layer, and the second insulating layer as a mask, to form first contact holes each disposed on a corresponding one of the second impurity regions; and
forming the first wiring conductor layer and the second wiring conductor layer, the first wiring conductor layer being connected to the second impurity regions at the top portions of the first semiconductor pillar and the third semiconductor pillar through corresponding first contact holes of the first contact holes, the second wiring conductor layer being connected to the second impurity regions at the top portions of the second semiconductor pillar and the fourth semiconductor pillar through corresponding first contact holes of the first contact holes.

10. The method for manufacturing a memory device including a pillar-shaped semiconductor element according to claim 4, further comprising the steps of:
etching the first conductor layer by using the seventh mask material layers, the second mask material layer, and the third mask material layer as a mask, to form the second gate conductor layer and the third gate conductor layer;
forming a third insulating layer surrounding side surfaces of the second gate conductor layer, the third gate conductor layer, the second mask material layer, and the third mask material layer;
etching the seventh mask material layers on the top portions of the first to fourth semiconductor pillars by using the second mask material layer, the third mask material layer, and the third insulating layer as a mask, to form second contact holes each disposed on a corresponding one of the second impurity regions; and
forming the first wiring conductor layer and the second wiring conductor layer, the first wiring conductor layer being connected to the second impurity regions at the top portions of the first semiconductor pillar and the third semiconductor pillar through corresponding second contact holes of the second contact holes, the second wiring conductor layer being connected to the second impurity regions at the top portions of the second semiconductor pillar and the fourth semiconductor pillar through corresponding second contact holes of the second contact holes.

11. The method for manufacturing a memory device including a pillar-shaped semiconductor element according to claim 4, further comprising the steps of:
etching the first conductor layer by using the seventh mask material layers, the fourth mask material layers, the fifth mask material layer, and the sixth mask material layer as a mask, to form the second gate conductor layer and the third gate conductor layer;
forming a fourth insulating layer surrounding side surfaces of the second gate conductor layer, the third gate conductor layer, and the fourth mask material layers;
etching the seventh mask material layers on the top portions of the first to fourth semiconductor pillars by using the fourth insulating layer and the fourth mask material layers as a mask, to form third contact holes each disposed on a corresponding one of the second impurity regions; and
forming the first wiring conductor layer and the second wiring conductor layer, the first wiring conductor layer being connected to the second impurity regions at the top portions of the first semiconductor pillar and the third semiconductor pillar through corresponding third contact holes of the third contact holes, the second wiring conductor layer being connected to the second impurity regions at the top portions of the second semiconductor pillar and the fourth semiconductor pillar through corresponding third contact holes of the third contact holes.

12. The method for manufacturing a memory device including a pillar-shaped semiconductor element according to claim 1, wherein
the second gate insulating layers are formed so as to surround the side surfaces of the first to fourth semiconductor pillars and be connected onto the first gate conductor layer such that the first gate conductor layer is insulated from the second gate conductor layer and the third gate conductor layer in the vertical direction.

13. The method for manufacturing a memory device including a pillar-shaped semiconductor element according to claim 1, wherein
the first to fourth semiconductor pillars, the first gate conductor layer, the second gate conductor layer, the third gate conductor layer, the first impurity region, and the second impurity regions are formed so as to perform the data write operation and the data erase operation, the data write operation being an operation of holding, in an inside of any or all of the first to fourth semiconductor pillars, a positive hole group generated by an impact ionization phenomenon or a gate-induced drain-leakage current, the data erase operation being an operation of discharging the positive hole group from the inside of any or all of the first to fourth semiconductor pillars by controlling voltages to be applied to the first to third gate conductor layers, the first impurity region, and the second impurity regions.

14. The method for manufacturing a memory device including a pillar-shaped semiconductor element according to claim 1, further comprising the steps of:
forming third gate insulating layers each surrounding a corresponding one of the first to fourth semiconductor pillars at upper portions of the second gate conductor layer and the third gate conductor layer in the vertical direction; and
forming a fourth gate conductor layer and a fifth gate conductor layer, the fourth gate conductor layer surrounding the third gate insulating layers and being continuous between the first semiconductor pillar and the second semiconductor pillar on the first line, the fifth gate conductor layer being continuous between the third semiconductor pillar and the fourth semiconductor pillar on the second line.

15. The method for manufacturing a memory device including a pillar-shaped semiconductor element according to claim 1, wherein
the forming of the first gate conductor layer includes forming the first gate conductor layer divided into a sixth gate conductor layer and a seventh gate conductor layer, the sixth gate conductor layer being continuous between the first semiconductor pillar and the second semiconductor pillar on the first line, the seventh gate conductor layer being continuous between the third semiconductor pillar and the fourth semiconductor pillar on the second line.
